(19) United States
(12) Patent Application Publication
(10) Pub. No.: US 2026/0332300 A1
(43) Pub. Date: Oct. 22, 2026

(54) RATE MATCHING METHOD AND APPARATUSES

(71) Applicant: Huawei Technologies Co., Ltd., Shenzhen (CN)

(72) Inventors: Huazi Zhang, Zhejiang (CN); Jianglei Ma, Ottawa (CA); Wen Tong, Ottawa (CA)

(21) Appl. No.: 19/697,019

(22) Filed: Jun. 3, 2026

Related U.S. Application Data
(63) Continuation of application No. PCT/CN2024/084492, filed on Mar. 28, 2024.
(60) Provisional application No. 63/605,681, filed on Dec. 4, 2023.

(51) Int. Cl. H04L 1/00

(52) U.S. Cl. CPC H04L 1/0067; H04L 1/0003; H04L 1/0061; H04L 1/0071

(57) ABSTRACT

The present disclosure provides a method and related products. The method includes: obtaining a first bit sequence; performing rate matching on the first bit sequence to obtain a second bit sequence, where code bits of the second bit sequence are included in the first bit sequence, and an ordering characteristic of the code bits in the second bit sequence conforms to an ordering characteristic of the code bits in the first bit sequence; outputting the second bit sequence. In this way, the rate matching process can preserve a desired ordering characteristic of a bit sequence, which may create opportunities for hardware optimization or simplification, or further help with error correction.

### CROSS-REFERENCE TO RELATED APPLICATIONS

This application is a continuation of International Patent Application No. PCT/CN2024/084492, filed on Mar. 28, 2024, which claims the benefit of U.S. Provisional Application No. 63/605,681, filed on Dec. 4, 2023. The entire disclosures of the above patent applications are incorporated herein by reference.

### TECHNICAL FIELD

The present disclosure relates to the field of wireless communication technologies, and in particular, to a rate matching method and an apparatus, a device, a system and a storage medium.

### BACKGROUND

Generally, source bits to be transmitted would be encoded into code bits in a communication system, to provide error correction capability against adversary channel conditions such as noise and interference. Rate matching would be performed after channel encoding, by either puncturing/shortening or repeating some code bits. The purpose of this operation is to obtain a code bit sequence of desired length for transmission over limited channel resources. Channel interleaving would be applied after channel encoding and rate matching by permuting the code bits. The purpose is to provide stable or superior performance under high-order modulation or in a fading channel. In practice, implementations of rate matching schemes, especially for Polar, LDPC, and Turbo codes, may involve code bit interleaving before bit selection.

This background information is provided to reveal information believed by the applicant to be of possible relevance to the present disclosure. No admission is necessarily intended, nor should be construed, that any of the preceding information constitutes prior art against the present disclosure.

### SUMMARY

In a first aspect, an embodiment of the present disclosure provides a method, including:
obtaining a first bit sequence;
performing rate matching on the first bit sequence to obtain a second bit sequence, where code bits of the second bit sequence are included in the first bit sequence, and an ordering characteristic of the code bits in the second bit sequence conforms to an ordering characteristic of the code bits in the first bit sequence;
outputting the second bit sequence.

A transmitting device obtains a first bit sequence, performs rate matching on the first bit sequence to obtain a second bit sequence, where code bits of the second bit sequence are included in the first bit sequence, and an ordering characteristic of the code bits in the second bit sequence conforms to an ordering characteristic of the code bits in the first bit sequence, and the transmitting device outputs the second bit sequence. In this way, the rate matching process can preserve a desired ordering characteristic of a bit sequence, there may be opportunities for hardware optimization or simplification, processing on the receiving device can be simplified, thereby increasing the throughput.

In an implementation of the first aspect, the obtaining the first bit sequence includes:
encoding information bits by using a first encoding method to obtain the first bit sequence.

By encoding the information bits using an appropriate method, the first bit sequence can be prepared to withstand the effects of channel impairments and noise, ensuring reliable and accurate transmission or storage of the data.

In an implementation of the first aspect, the ordering characteristic includes a relative ordering of code bits, and the ordering characteristic of the code bits in the second bit sequence conforming to an ordering characteristic of the code bits in the first bit sequence includes:
the relative ordering of the code bits in the second bit sequence is the same as the relative ordering of the code bits in the first bit sequence.

Since the relative ordering of the code bits in the second bit sequence is the same as the relative ordering of the code bits in the first bit sequence, the receiving device no longer needs a de-interleaver during de-rate matching, thereby simplifying processing and improving the overall efficiency and reliability of the communication system.

In an implementation of the first aspect, the performing rate matching on the first bit sequence to obtain the second bit sequence includes:
performing rate matching on the first bit sequence by using a first mode or a second mode.

In an implementation of the first aspect, the performing rate matching on the first bit sequence by using the first mode includes:
performing rate matching interleaving on the first bit sequence to obtain a third bit sequence;
performing rate matching on the third bit sequence by reading out a number of code bits from the third bit sequence, to obtain a fourth bit sequence, where the number of code bits of the fourth bit sequence is less than, equal to or larger than the number of code bits of the third bit sequence; and
performing de-interleaving on the fourth bit sequence to obtain the second bit sequence.

The transmitting device can ensure that code bits of the rate matching output sequence, i.e. the second bit sequence can maintain their original order as in the original bit sequence, i.e. the first bit sequence, by performing de-interleaving on the fourth bit sequence which is read out from the third bit sequence. By exploiting this property, the decoder no longer needs a de-interleaver during de-rate matching which can simplify the processing and hardware structure of the decode and greatly increases the throughput.

In an implementation of the first aspect, the performing de-interleaving on the fourth bit sequence to obtain the second bit sequence includes:
sorting the fourth bit sequence by a first order according to a rate matching scheme.

In an implementation of the first aspect, the rate matching scheme includes repetition or puncturing, and the first order is ascending order.

In an implementation of the first aspect, the rate matching scheme includes shortening, and the first order is descending order.

By sorting the fourth bit sequence according to the defined order, the original order of code bits can be reconstructed to obtain the desired second bit sequence.

In an implementation of the first aspect, the performing rate matching on the third bit sequence to obtain the fourth bit sequence includes:
performing bit selection on the third bit sequence based on a rate matching scheme to obtain the fourth bit sequence.

In an implementation of the first aspect, the performing bit selection on the third bit sequence based on a rate matching scheme to obtain the fourth bit sequence includes:
writing code bits of the third bit sequence into a buffer; and
reading out code bits from the buffer starting from a first position according to the rate matching scheme to obtain the fourth bit sequence.

By employing bit selection from the buffer, the communication system can control the rate at which the interleaved code bits are extracted. This selective reading mechanism allows for precise adjustment of the data rate and facilitates the generation of the final output sequence based on the interleaved input bit sequence.

In an implementation of the first aspect, the rate matching scheme includes repetition or shortening, the first position is a starting position of the third bit sequence.

In an implementation of the first aspect, the rate matching scheme includes puncturing, and the first position is a mother code length of the first bit sequence minus a rate matching output length.

In an implementation of the first aspect, the performing bit selection on the third bit sequence according to a rate matching scheme to obtain the fourth bit sequence includes:
writing code bits of the third bit sequence into a buffer; and
in a case that a starting position is pre-defined for a specific redundancy version, reading out code bits from the buffer starting from the starting position to obtain the fourth bit sequence, where the fourth bit sequence has a length determined according to a channel characteristic.

By performing bit selection from a starting position which is determined according to the rate matching scheme used, the rate matching can be achieved, and the length and bits arrangement of the fourth bit sequence can be adjusted based on the channel or transmission requirements. In this way, the system can improve the transmission performance.

In an implementation of the first aspect, the performing de-interleaving on the fourth bit sequence to obtain the second bit sequence includes:
in a case that a starting position is pre-defined for a specific redundancy version, sorting the fourth bit sequence by ascending order.

In an implementation of the first aspect, the performing rate matching interleaving on the first bit sequence to obtain the third bit sequence includes:
performing, by using an interleaver, rate matching interleaving on the first bit sequence to obtain a third bit sequence;
where the interleaver includes: a triangular interleaver, a block interleaver, a subblock interleaver, a bit-reversed interleaver, a cyclic shift interleaver, a pseudo-random interleaver, or a quadratic permutation polynomials (QPP) interleaver.

Various interleavers may be used according to actual demands, thereby adapting to different application scenarios.

In an implementation of the first aspect, the performing rate matching on the first bit sequence by using the second mode includes:
performing, by using a pre-defined function, bit selection on the first bit sequence to obtain the second bit sequence.

The transmitting device may use a pre-defined function to perform bit selection on the first bit sequence to obtain the second bit sequence. In this way, the rate matching interleaver can be omitted, removed, or bypassed entirely, which can simplify the system structure, increase the throughput and improve the communication efficiency. Further, the bit selection can be performed on the code bits in parallel such that the overall throughput can be greatly increased.

In an implementation of the first aspect, the performing, by using a pre-defined function, bit selection on the first bit sequence includes:
determining, for each of code bits of the first bit sequence, by using the pre-defined function and according to a rate matching output length and a mother code length, whether the respective code bit is to be transmitted; and
obtaining, according to code bits that are determined to be transmitted, the second bit sequence.

By eliminating the need for a rate matching interleaver, the system complexity and processing time can be reduced. The use of a pre-defined function also enables the system to adapt to different transmission requirements and channel conditions, making better use of available resources.

In an implementation of the first aspect, the performing, by using a pre-defined function, bit selection on the first bit sequence includes:
obtaining, for each of code bits of the first bit sequence, a binary value by applying the pre-defined function on each of code bits of the first bit sequence, wherein the binary value, which is an output of the pre-defined function corresponding to each of the code bits, indicates whether to select the respective code bit into the second bit sequence;
obtaining the second bit sequence based on the binary value of each of the code bits of the first bit sequence.

In an implementation of the first aspect, the performing, by using a pre-defined function, bit selection on the first bit sequence includes:
determining, for each of code bits of the first bit sequence, by using the pre-defined function and according to a rate matching output length and a mother code length, how many times each of the respective code bit is to be transmitted; and
obtaining, according to the times that each of the respective code bits are determined to be transmitted, the second bit sequence.

The transmitting device may determine how many times each of the respective code bit is to be transmitted, especially when the rate matching scheme is repetition, and may obtain the second bit sequence according to the times that each of the respective code bits are determined to be transmitted. In this way, the rate matching can be achieved by eliminating the need for a rate matching interleaver, and the system complexity and processing time can be reduced.

In an implementation of the first aspect, the pre-defined function includes: a function for a block interleaver, a function for a subblock interleaver, a function for a bit-reversed interleaver, a function for a cyclic shift interleaver.

Various functions may be preset for different types of interleavers to adapt to different application scenarios with different transmission requirements. When a specific type of interleaver is required to be used, bit selection can be performed by using a corresponding function, thereby improving flexibility of the system.

In an implementation of the first aspect, the pre-defined function includes a function for a block interleaver, and the determining, for each code bit of code bits of the first bit sequence, by using the pre-defined function and according to a rate matching output length and a mother code length whether the each code bit is to be transmitted includes at least one of the following steps:
comparing first position information of each code bit and a first threshold, where the first position information of each code bit is obtained according to an index of each code bit and dimension information of the block interleaver, and the first threshold is obtained according to the rate matching output length and the dimension information of the block interleaver;
determining, according to a comparing result, whether each code bit in the first bit sequence is to be transmitted.

By using the function for a block interleaver, bit selection can be performed easily, which can simplify the rate matching, reduce computational complexity, and increase the overall throughput.

In an implementation of the first aspect, the pre-defined function includes a function for a subblock interleaver, and the determining, for each code bit of code bits in the first bit sequence, by using the pre-defined function and according to a rate matching output length and a mother code length, whether the each code bit is to be transmitted includes at least one of the following steps:
determining a rate matching scheme according to a code rate;
in a case that the rate matching scheme is puncturing, determining that each code bit belonging to a subblock with an index smaller than a fourth threshold is not to be transmitted and determining that each code bit belonging to a subblock with an index greater than the fourth threshold is to be transmitted; for code bits belonging to a subblock with an index equal to the fourth threshold, determining a code bit is not to be transmitted when an index of the code bit modulo a subblock length is smaller than a fifth threshold, and determining a code bit is to be transmitted when an index of the code bit modulo the subblock length is equal to or greater than the fifth threshold; where the fourth threshold and the fifth threshold are determined based on a rate matching output length, a mother code length and the subblock length; or
in a case that the rate matching scheme is shortening, determining that each code bit belonging to a subblock with an index smaller than a sixth threshold is to be transmitted and determining that each code bit belonging to a subblock with an index greater than the sixth threshold is not to be transmitted; for code bits belonging to a subblock with an index equal to the sixth threshold, determining a code bit is not to be transmitted when an index of the code bit modulo a subblock length is smaller than a seventh threshold, and determining a code bit is to be transmitted, when an index of the code bit modulo the subblock length is equal to or greater than the seventh threshold; where the sixth threshold and the seventh threshold are determined based on a rate matching output length and the subblock length.

By using the function for a subblock interleaver to perform bit selection, high parallelism can be provided, thereby increasing the throughput of the system.

In an implementation of the first aspect, the pre-defined function includes a function for a bit-reversed interleaver, and the determining, for each code bit of code bits in the first bit sequence, by using the pre-defined function and according to a rate matching output length and a mother code length, whether the each code bit is to be transmitted includes at least one of the following steps:
applying a bit-reversal function on an index of each code bit to obtain a bit-reversed index of each code bit;
determining a rate matching scheme according to a code rate;
in a case that the rate matching scheme is puncturing, determining whether each code bit is to be transmitted by comparing the bit-reversed index of each code bit and a second threshold, where the second threshold is determined by a rate matching output length and a mother code length; or
in a case that the rate matching scheme is shortening, determining whether each code bit is to be transmitted by comparing the bit-reversed index of each code bit and a third threshold, where the third threshold is determined by a rate matching output length.

In an implementation of the first aspect, the in a case that the rate matching scheme is puncturing, determining whether each code bit is to be transmitted by comparing the bit-reversed index of each code bit and a second threshold includes:
in a case that a bit-reversed index of a code bit in the first bit sequence is less than the second threshold, determining the code bit not to be transmitted;
in a case that a bit-reversed index of a code bit in the first bit sequence is equal to or larger than the second threshold, determining the code bit to be transmitted;
where the second threshold is equal to the mother code length minus the rate matching output length.

In an implementation of the first aspect, the in a case that the rate matching is shortening, determining whether each code bit in the first bit sequence to be transmitted by comparing the bit-reversed index of each code bit and a third threshold, where the third threshold is determined by a rate matching output length includes:
in a case that a bit-reversed index of a code bit in the first bit sequence is less than the third threshold, determining that the code bit is to be transmitted;
in a case that a bit-reversed index of a code bit in the first bit sequence is equal to or larger than the third threshold, determining that the code bit is not to be transmitted;
where the third threshold is equal to the rate matching output length.

By using the function for a bit-reversed interleaver to perform bit selection, simplicity in implementation and low computational complexity can be achieved, and the requirements for memory resources are small.

In an implementation of the first aspect, the pre-defined function includes a function for a cyclic shift interleaver, and the determining, for each code bit of code bits in the first bit sequence, by using the pre-defined function and according to a rate matching output length and a mother code length, whether the each code bit in the first bit sequence is to be transmitted includes at least one of the following steps:
obtaining third position information of each code bit in the first bit sequence by shifting an index of each code bit in the first bit sequence circularly by a pre-defined offset;
determining a rate matching scheme according to a code rate;
in a case that the rate matching scheme is puncturing, determining whether each code bit is to be transmitted by comparing the third position information of each code bit and a second threshold, where the second threshold is determined by a rate matching output length and a mother code length; or
in a case that the rate matching scheme is shortening, determining whether each code bit is to be transmitted by comparing the third position information of each code bit of each code bit and a third threshold, where the third threshold is determined by a rate matching output length.

In an implementation of the first aspect, the in a case that the rate matching scheme is puncturing, determining whether each code bit is to be transmitted by comparing the third position information of each code bit and a second threshold includes:
in a case that third position information of a code bit in the first bit sequence is less than the second threshold, determining that the code bit is not to be transmitted;
in a case that third position information of a code bit in the first bit sequence is equal to or larger than the second threshold, determining that the code bit is to be transmitted;
where the second threshold is equal to the mother code length minus the rate matching output length.

In an implementation of the first aspect, the in a case that the rate matching scheme is shortening, determining whether each code bit is to be transmitted by comparing the third position information of each code bit of each code bit and a third threshold includes:
in a case that third position information of a code bit in the first bit sequence is less than the third threshold, determining that the code bit is to be transmitted;
in a case that third position information of a code bit in the first bit sequence is equal to or larger than the third threshold, determining that the code bit is not to be transmitted;
where the third threshold is equal to the rate matching output length.

By using the function for a cyclic shift interleaver to perform bit selection, the position of code bits is adjusted and certain bits are selectively omitted based on the determined scheme, the system can optimize the use of available bandwidth and improve the robustness of data transmission against errors.

In an implementation of the first aspect, the performing rate matching on the first bit sequence by using the first mode or the second mode includes:
determining, according to transmission requirement, to perform rate matching on the first bit sequence by using the first mode or a second mode.

In an implementation of the first aspect, determining, according to transmission requirement, to perform rate matching on the first bit sequence by using a first mode or a second mode includes:
in a case that the transmission requirement is ultra-high throughput, determining to perform rate matching on the first bit sequence by using the second mode;
in a case that the transmission requirement is a requirement other than ultra-high throughput, determining to perform rate matching on the first bit sequence by using the first mode.

In an implementation of the first aspect, the first encoding method includes LDPC coding, where the performing rate matching on the first bit sequence by using a first mode or a second mode includes:
in a case that a preset base graph is used, determining to perform rate matching on the first bit sequence by using a second mode;
in a case that a base graph other than the preset base graph is used, determining to perform rate matching on the first bit sequence by using a first mode.

In an implementation of the first aspect, wherein the preset base graph includes a base graph designed for a high-throughput communication.

In an implementation of the first aspect, the first encoding method includes LDPC coding or polar coding, where the performing rate matching on the first bit sequence by using a first mode or a second mode includes:
in a case that a preset MCS index is used, determining to perform rate matching on the first bit sequence by using a second mode;
in a case that an MCS index other than the preset MCS index is used, determining to perform rate matching on the first bit sequence by using a first mode.

The ability to determine which mode to use based on transmission requirements gives the system flexibility to adapt to different scenarios. By selecting the appropriate mode for rate matching, the system can allocate resources effectively, the communication efficiency can be improved, and better performance metrics in the communication system can be achieved.

In a second aspect, an embodiment of the present disclosure provides an apparatus including various modules configured to execute the method according to the first aspect or any possible implementation of the first aspect.

In a third aspect, an embodiment of the present disclosure provides an apparatus including processing circuitry for executing the method according to the first aspect or any possible implementation of the first aspect.

In a fourth aspect, an embodiment of the present disclosure provides an encoder including the apparatus according to the second aspect, or the apparatus according to the third aspect.

In a fifth aspect, an embodiment of the present disclosure provides an electronic device including an encoder for executing the method according to the first aspect or any possible implementation of the first aspect.

In a sixth aspect, an embodiment of the present disclosure provides a computer-readable medium storing computer execution instructions which, when executed by a processor, causes the processor to execute the method according to the first aspect or any possible implementation of the first aspect.

In a seventh aspect, an embodiment of the present disclosure provides a computer program product including computer execution instructions which, when executed by a processor, causes the processor to execute the method according to the first aspect or any possible implementation of the first aspect.

The present disclosure provides a method, including: obtaining a first bit sequence; performing rate matching on the first bit sequence to obtain a second bit sequence, where code bits of the second bit sequence are included in the first bit sequence, and an ordering characteristic of the code bits in the second bit sequence conforms to an ordering characteristic of the code bits in the first bit sequence; outputting the second bit sequence. In this way, the rate matching process can preserve a desired ordering characteristic of a bit sequence, there may be opportunities for hardware optimization or simplification, processing on the receiving device can be simplified, thereby increasing the throughput.

### BRIEF DESCRIPTION OF DRAWINGS

Reference will now be made, by way of example, to the accompanying drawings which show example embodiments of the present disclosure.

FIG. 1 is a simplified schematic illustration of a communication system according to one or more embodiments of the present disclosure.

FIG. 2 is a schematic illustration of an example communication system according to one or more embodiments of the present disclosure.

FIG. 3 is a schematic illustration of a basic component structure of a communication system according to one or more embodiments of the present disclosure.

FIG. 4 illustrates a block diagram of a device in a communication system according to one or more embodiments of the present disclosure.

FIG. 5 is a schematic diagram of an example of a polar code according to one or more embodiments of the present disclosure.

FIG. 6 is a schematic diagram showing a sub-block interleaver pattern table reproduced from a 3GPP standard specification, with directions for puncturing and shortening marked.

FIG. 7 is a schematic diagram of an example of polar code rate matching according to one or more embodiments of the present disclosure.

FIG. 8 is a schematic diagram of an example of polar HARQ according one or more embodiments of the present disclosure.

FIG. 9 is a schematic diagram of an example of an encoding process according one or more embodiments of the present disclosure.

FIG. 10 is a schematic diagram of an example of an encoding process according one or more embodiments of the present disclosure.

FIG. 11 is a schematic diagram of an example of a polar transform matrix according one or more embodiments of the present disclosure.

FIG. 12 is a schematic diagram illustrating an interleaver-based rate matching method according to one or more example embodiments of the present disclosure.

FIG. 13 is a schematic diagram of an example of an indicator function according to one or more example embodiments of the present disclosure.

FIG. 14 is a schematic diagram illustrating an interleaver-free rate matching method according to one or more example embodiments of the present disclosure.

FIG. 15 shows a schematic flowchart of a rate matching method according to one or more example embodiments of the present disclosure.

FIG. 16 shows a schematic structural diagram of an apparatus according to one or more example embodiments of the present disclosure.

### DESCRIPTION OF EMBODIMENTS

In the following description, reference is made to the accompanying figures, which form part of the present disclosure, and which show, by way of illustration, specific aspects of embodiments of the present disclosure or specific aspects in which embodiments of the present disclosure may be used. It is understood that embodiments of the present disclosure may be used in other aspects and include structural or logical changes not depicted in the figures. The following detailed description, therefore, is not to be taken in a limiting sense, and the scope of the present disclosure is defined by the appended claims.

In wireless communications, channel quality is constantly changing due to the fading effects at both fast and slow scale. Accordingly, channel coding has always been designed to adapt to the channel states. Modulation coding scheme (MCS) adaptation is a powerful method to combat varying channel states, in which the modulation order and code length and coding rate can be changed in real time. Therefore, it requires that a channel coding scheme can flexibly change the code length and code rate in a fine-grained way, and at the same time achieve good error correction performance in all possible configurations. This fine-grained flexibility of channel codes is one of the most challenging problem for engineers in this domain.

At the same time, the complexity of both encoding and decoding algorithms need to be sufficiently low. In hardware, complexity can be evaluated through measuring chip area and energy efficiency. They are related to algorithmic complexity, but are more closely related to hardware cost and battery life. Therefore, there exists a desire to reduce implementation complexity when designing coding schemes.

Future communication systems, such as so-called sixth-generation (6G) systems, may aim to support several challenging scenarios, including for example immersive communication, massive communication, and hyper reliable and low-latency communication. The KPIs that are related to channel coding include coding gain, reliability, throughput, latency and their tradeoffs. For example, the throughput target of 6G may reach above 1 Tbps, and the energy efficiency target may decrease to 1 pJ/bit. Meanwhile, a coding scheme supporting flexible rate matching and IR-HARQ schemes is also beneficial. Accordingly, it is desirable yet challenging to design a code ensemble to fulfill all these KPIs and capabilities.

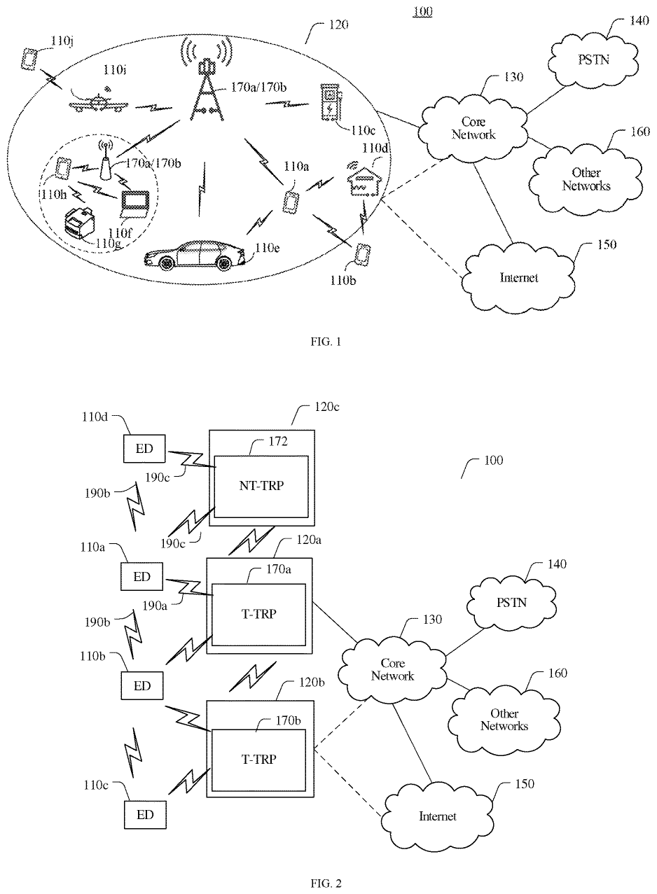

Referring to FIG. 1, as an illustrative example without limitation, a simplified schematic illustration of a communication system is provided. The communication system 100 comprises a radio access network 120. The radio access network 120 may be a next generation (e.g. sixth generation (6G) or later) radio access network, or a legacy (e.g. 5G, 4G, 3G or 2G) radio access network. One or more communication electronic devices (ED) 110a, 110b, 110c, 110d, 110e, 110f, 110g, 110h, 110i, 110j (generically referred to as 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also the communication system 100 comprises a public switched telephone network (PSTN) 140, the internet 150, and other networks 160.

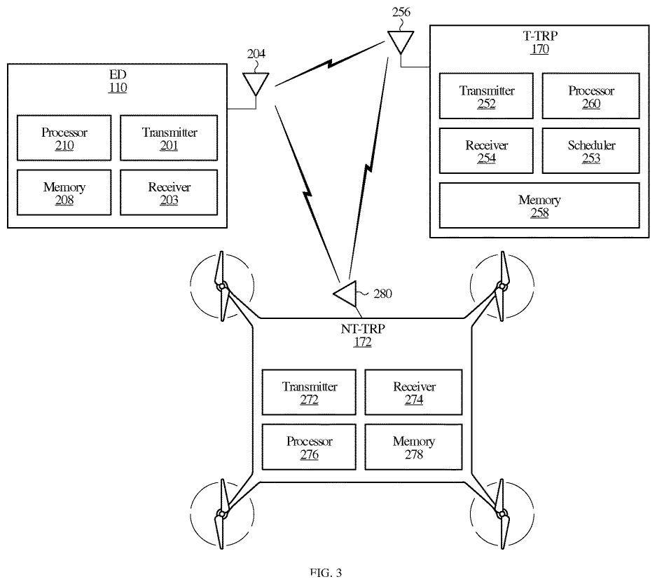

FIG. 2 illustrates an example communication system 100. In general, the communication system 100 enables multiple wireless or wired elements to communicate data and other content. The purpose of the communication system 100 may be to provide content, such as voice, data, video, and/or text, via broadcast, multicast, groupcast, unicast, etc. The communication system 100 may operate by sharing resources, such as carrier spectrum bandwidth, between its constituent elements. The communication system 100 may include a terrestrial communication system and/or a non-terrestrial communication system. The communication system 100 may provide a wide range of communication services and applications (such as earth monitoring, remote sensing, passive sensing and positioning, navigation and tracking, autonomous delivery and mobility, etc.). The communication system 100 may provide a high degree of availability and robustness through a joint operation of a terrestrial communication system and a non-terrestrial communication system. For example, integrating a non-terrestrial communication system (or components thereof) into a terrestrial communication system can result in what may be considered a heterogeneous network comprising multiple layers. Compared to conventional communication networks, the heterogeneous network may achieve better overall performance through efficient multi-link joint operation, more flexible functionality sharing, and faster physical layer link switching between terrestrial networks and non-terrestrial networks.

The terrestrial communication system and the non-terrestrial communication system could be considered sub-systems of the communication system. In the example shown in FIG. 2, the communication system 100 includes electronic devices (ED) 110a, 110b, 110c, nod (generically referred to as ED 110), radio access networks (RANs) 120a, 120b, a non-terrestrial communication network 120c, a core network 130, a public switched telephone network (PSTN) 140, the Internet 150, and other networks 160. The RANs 120a, 120b include respective base stations (BSs) 170a, 170b, which may be generically referred to as terrestrial transmit and receive points (T-TRPs) 170a, 170b. The non-terrestrial communication network 120c includes an access node 172, which may be generically referred to as a non-terrestrial transmit and receive point (NT-TRP) 172.

Any ED no may be alternatively or additionally configured to interface, access, or communicate with any T-TRP 170a,170b and NT-TRP 172, the Internet 150, the core network 130, the PSTN 140, the other networks 160, or any combination of the preceding. In some examples, ED 110a may communicate an uplink and/or downlink transmission over a terrestrial air interface 190a with T-TRP 170a. In some examples, the EDs 110a, 110b, 110c, and 110d may also communicate directly with one another via one or more sidelink air interfaces 190b. In some examples, ED 110d may communicate an uplink and/or downlink transmission over a non-terrestrial air interface 190c with NT-TRP 172.

The air interfaces 190a and 190b may use similar communication technology, such as any suitable radio access technology. For example, the communication system 100 may implement one or more channel access methods, such as code division multiple access (CDMA), space division multiple access (SDMA), time division multiple access (TDMA), frequency division multiple access (FDMA), orthogonal FDMA (OFDMA), or single-carrier FDMA (SC-FDMA, also known as discrete Fourier transform spread OFDMA, DFT-s-OFDMA) in the air interfaces 190a and 190b. The air interfaces 190a and 190b may utilize other higher dimension signal spaces, which may involve a combination of orthogonal and/or non-orthogonal dimensions.

The non-terrestrial air interface 190c can enable communication between the ED 110d and one or multiple NT-TRPs 172 via a wireless link or simply a link. For some examples, the link is a dedicated connection for unicast transmission, a connection for broadcast transmission, or a connection between a group of EDs 110 and one or multiple NT-TRPs 172 for multicast transmission.

The RANs 120a and 120b are in communication with the core network 130 to provide the EDs 110a 110b, and 110c with various services such as voice, data, and other services. The RANs 120a and 120b and/or the core network 130 may be in direct or indirect communication with one or more other RANs (not shown), which may or may not be directly served by core network 130, and may or may not employ the same radio access technology as RAN 120a, RAN 120b or both. The core network 130 may also serve as a gateway access between (i) the RANs 120a and 120b or EDs 110a 110b, and 110c or both, and (ii) other networks (such as the PSTN 140, the Internet 150, and the other networks 160). In addition, some or all of the EDs 110a 110b, and 110c may include functionality for communicating with different wireless networks over different wireless links using different wireless technologies and/or protocols. Instead of wireless communication (or in addition thereto), the EDs 110a 110b, and 110c may communicate via wired communication channels to a service provider or switch (not shown), and to the Internet 150. PSTN 140 may include circuit switched telephone networks for providing plain old telephone service (POTS). Internet 150 may include a network of computers and subnets (intranets) or both, and incorporate protocols, such as Internet Protocol (IP), Transmission Control Protocol (TCP), User Datagram Protocol (UDP). EDs 110a 110b, and 110c may be multimode devices capable of operation according to multiple radio access technologies, and incorporate multiple transceivers necessary to support such.

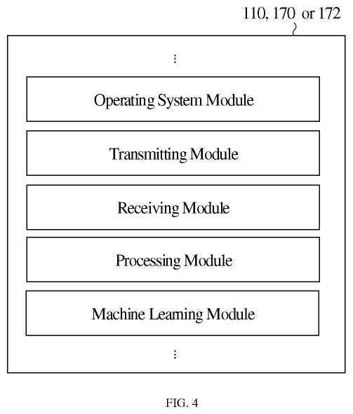

FIG. 3 illustrates another example of an ED 110 and a base station 170a, 170b and/or 170c. The ED 110 is used to connect persons, objects, machines, etc. The ED 110 may be widely used in various scenarios including, for example, cellular communications, device-to-device (D2D), vehicle to everything (V2X), peer-to-peer (P2P), machine-to-machine (M2M), machine-type communications (MTC), internet of things (IoT), virtual reality (VR), augmented reality (AR), mixed reality (MR), metaverse, digital twin, industrial control, self-driving, remote medical, smart grid, smart furniture, smart office, smart wearable, smart transportation, smart city, drones, robots, remote sensing, passive sensing, positioning, navigation and tracking, autonomous delivery and mobility, etc.

Each ED no represents any suitable end user device for wireless operation and may include such devices (or may be referred to) as a user equipment/device (UE), a wireless transmit/receive unit (WTRU), a mobile station, a fixed or mobile subscriber unit, a cellular telephone, a station (STA), a machine type communication (MTC) device, a personal digital assistant (PDA), a smartphone, a laptop, a computer, a tablet, a wireless sensor, a consumer electronics device, a smart book, a vehicle, a car, a truck, a bus, a train, or an IoT device, wearable devices (such as a watch, a pair of glasses, head mounted equipment, etc.), an industrial device, or an apparatus in (e.g. communication module, modem, or chip) or comprising the forgoing devices, among other possibilities. Future generation EDs no may be referred to using other terms. The base station 170a and 170b is a T-TRP and will hereafter be referred to as T-TRP 170. Also shown in FIG. 3, a NT-TRP will hereafter be referred to as NT-TRP 172. Each ED no connected to T-TRP 170 and/or NT-TRP 172 can be dynamically or semi-statically turned-on (i.e., established, activated, or enabled), turned-off (i.e., released, deactivated, or disabled) and/or configured in response to one of more of: connection availability and connection necessity.

The ED no includes a transmitter 201 and a receiver 203 coupled to one or more antennas 204. Only one antenna 204 is illustrated to avoid congestion in the drawing. One, some, or all of the antennas 204 may alternatively be panels. The transmitter 201 and the receiver 203 may be integrated, e.g. as a transceiver. The transceiver is configured to modulate data or other content for transmission by at least one antenna 204 or network interface controller (NIC). The transceiver is also configured to demodulate data or other content received by the at least one antenna 204. Each transceiver includes any suitable structure for generating signals for wireless or wired transmission and/or processing signals received wirelessly or by wire. Each antenna 204 includes any suitable structure for transmitting and/or receiving wireless or wired signals.

The ED 110 includes at least one memory 208. The memory 208 stores instructions and data used, generated, or collected by the ED 110. For example, the memory 208 could store software instructions or modules configured to implement some or all of the functionality and/or embodiments described herein and that are executed by one or more processing unit(s) (e.g., a processor 210). Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, on-processor cache, and the like.

The ED 110 may further include one or more input/output devices (not shown) or interfaces (such as a wired interface to the Internet 150 in FIG. 1). The input/output devices or interfaces permit interaction with a user or other devices in the network. Each input/output device or interface includes any suitable structure for providing information to or receiving information from a user, and/or for network interface communications. Suitable structures include, for example, a speaker, microphone, keypad, keyboard, display, touch screen, etc.

The ED 110 includes the processor 210 for performing operations including those operations related to preparing a transmission for uplink transmission to the NT-TRP 172 and/or the T-TRP 170; those operations related to processing downlink transmissions received from the NT-TRP 172 and/or the T-TRP 170; and those operations related to processing sidelink transmission to and from another ED 110. Processing operations related to preparing a transmission for uplink transmission may include operations such as encoding, modulating, transmit beamforming, and generating symbols for transmission. Processing operations related to processing downlink transmissions may include operations such as receive beamforming, demodulating and decoding received symbols. Depending upon the embodiment, a downlink transmission may be received by the receiver 203, possibly using receive beamforming, and the processor 210 may extract signaling from the downlink transmission (e.g. by detecting and/or decoding the signaling). An example of signaling may be a reference signal transmitted by the NT-TRP 172 and/or by the T-TRP 170. In some embodiments, the processor 210 implements the transmit beamforming and/or the receive beamforming based on the indication of beam direction, e.g. beam angle information (BAI), received from the T-TRP 170. In some embodiments, the processor 210 may perform operations relating to network access (e.g. initial access) and/or downlink synchronization, such as operations relating to detecting a synchronization sequence, decoding and obtaining the system information, etc. In some embodiments, the processor 210 may perform channel estimation, e.g. using a reference signal received from the NT-TRP 172 and/or from the T-TRP 170.

Although not illustrated, the processor 210 may form part of the transmitter 201 and/or part of the receiver 203. Although not illustrated, the memory 208 may form part of the processor 210.

The processor 210, the processing components of the transmitter 201, and the processing components of the receiver 203 may each be implemented by the same or different one or more processors that are configured to execute instructions stored in a memory (e.g. in the memory 208). Alternatively, some or all of the processor 210, the processing components of the transmitter 201, and the processing components of the receiver 203 may each be implemented using dedicated circuitry, such as a programmed field-programmable gate array (FPGA), an application-specific integrated circuit (ASIC), or a hardware accelerator such as a graphics processing unit (GPU) or an artificial intelligence (AI) accelerator.

The T-TRP 170 may be known by other names in some implementations, such as a base station, a base transceiver station (BTS), a radio base station, a network node, a network device, a device on the network side, a transmit/receive node, a Node B, an evolved NodeB (eNodeB or eNB), a Home eNodeB, a next Generation NodeB (gNB), a transmission point (TP), a site controller, an access point (AP), a wireless router, a relay station, a terrestrial node, a terrestrial network device, a terrestrial base station, a base band unit (BBU), a remote radio unit (RRU), an active antenna unit (AAU), a remote radio head (RRH), a central unit (CU), a distributed unit (DU), a positioning node, among other possibilities. The T-TRP 170 may be a macro BS, a pico BS, a relay node, a donor node, or the like, or combinations thereof. The T-TRP 170 may refer to the forgoing devices or refer to apparatus (e.g. a communication module, a modem, or a chip) in the forgoing devices.

In some embodiments, the parts of the T-TRP 170 may be distributed. For example, some of the modules of the T-TRP 170 may be located remote from the equipment that houses the antennas 256 for the T-TRP 170, and may be coupled to the equipment that houses the antennas 256 over a communication link (not shown) sometimes known as front haul, such as common public radio interface (CPRI). Therefore, in some embodiments, the term T-TRP 170 may also refer to modules on the network side that perform processing operations, such as determining the location of the ED 110, resource allocation (scheduling), message generation, and encoding/decoding, and that are not necessarily part of the equipment that houses the antennas 256 of the T-TRP 170. The modules may also be coupled to other T-TRPs. In some embodiments, the T-TRP 170 may actually be a plurality of T-TRPs that are operating together to serve the ED 110, e.g. through the use of coordinated multipoint transmissions.

The T-TRP 170 includes at least one transmitter 252 and at least one receiver 254 coupled to one or more antennas 256. Only one antenna 256 is illustrated to avoid congestion in the drawing. One, some, or all of the antennas 256 may alternatively be panels. The transmitter 252 and the receiver 254 may be integrated as a transceiver. The T-TRP 170 further includes a processor 260 for performing operations including those related to: preparing a transmission for downlink transmission to the ED 110, processing an uplink transmission received from the ED 110, preparing a transmission for backhaul transmission to the NT-TRP 172, and processing a transmission received over backhaul from the NT-TRP 172. Processing operations related to preparing a transmission for downlink or backhaul transmission may include operations such as encoding, modulating, precoding (e.g. multiple input multiple output (MIMO) precoding), transmit beamforming, and generating symbols for transmission. Processing operations related to processing received transmissions in the uplink or over backhaul may include operations such as receive beamforming, demodulating received symbols, and decoding received symbols. The processor 260 may also perform operations relating to network access (e.g. initial access) and/or downlink synchronization, such as generating the content of synchronization signal blocks (SSBs), generating the system information, etc. In some embodiments, the processor 260 also generates an indication of beam direction, e.g. BAI, which may be scheduled for transmission by a scheduler 253. The processor 260 performs other network-side processing operations described herein, such as determining the location of the ED 110, determining where to deploy the NT-TRP 172, etc. In some embodiments, the processor 260 may generate signaling, e.g. to configure one or more parameters of the ED 110 and/or one or more parameters of the NT-TRP 172. Any signaling generated by the processor 260 is sent by the transmitter 252. Note that “signaling”, as used herein, may alternatively be called control signaling. Signaling may be transmitted in a physical layer control channel, e.g. a physical downlink control channel (PDCCH), in which case the signaling may be known as dynamic signaling. Signaling transmitted in a downlink physical layer control channel may be known as Downlink Control Information (DCI). Signaling transmitted in an uplink physical layer control channel may be known as Uplink Control Information (UCI). Signaling transmitted in a sidelink physical layer control channel may be known as Sidelink Control Information (SCI). Signaling may be included in a higher-layer (e.g., higher than physical layer) packet transmitted in a physical layer data channel, e.g. in a physical downlink shared channel (PDSCH), in which case the signaling may be known as higher-layer signaling, static signaling, or semi-static signaling. Higher-layer signaling may also refer to Radio Resource Control (RRC) protocol signaling or Media Access Control-Control Element (MAC-CE) signaling.

The scheduler 253 may be coupled to the processor 260. The scheduler 253 may be included within or operated separately from the T-TRP 170. The scheduler 253 may schedule uplink, downlink, sidelink, and/or backhaul transmissions, including issuing scheduling grants and/or configuring scheduling-free (e.g., “configured grant”) resources. The T-TRP 170 further includes a memory 258 for storing information and data. The memory 258 stores instructions and data used, generated, or collected by the T-TRP 170. For example, the memory 258 could store software instructions or modules configured to implement some or all of the functionality and/or embodiments described herein and that are executed by the processor 260.

Although not illustrated, the processor 260 may form part of the transmitter 252 and/or part of the receiver 254. Also, although not illustrated, the processor 260 may implement the scheduler 253. Although not illustrated, the memory 258 may form part of the processor 260.

The processor 260, the scheduler 253, the processing components of the transmitter 252, and the processing components of the receiver 254 may each be implemented by the same or different one or more processors that are configured to execute instructions stored in a memory, e.g. in the memory 258. Alternatively, some or all of the processor 260, the scheduler 253, the processing components of the transmitter 252, and the processing components of the receiver 254 may be implemented using dedicated circuitry, such as a programmed FPGA, a hardware accelerator (e.g., a GPU or AI accelerator), or an ASIC.

Although the NT-TRP 172 is illustrated as a drone only as an example, the NT-TRP 172 may be implemented in any suitable non-terrestrial form, such as satellites and high altitude platforms, including international mobile telecommunication base stations and unmanned aerial vehicles, for example. Also, the NT-TRP 172 may be known by other names in some implementations, such as a non-terrestrial node, a non-terrestrial network device, or a non-terrestrial base station. The NT-TRP 172 includes a transmitter 272 and a receiver 274 coupled to one or more antennas 280. Only one antenna 280 is illustrated to avoid congestion in the drawing. One, some, or all of the antennas may alternatively be panels. The transmitter 272 and the receiver 274 may be integrated as a transceiver. The NT-TRP 172 further includes a processor 276 for performing operations including those related to: preparing a transmission for downlink transmission to the ED 110, processing an uplink transmission received from the ED 110, preparing a transmission for backhaul transmission to T-TRP 170, and processing a transmission received over backhaul from the T-TRP 170. Processing operations related to preparing a transmission for downlink or backhaul transmission may include operations such as encoding, modulating, precoding (e.g. MIMO precoding), transmit beamforming, and generating symbols for transmission. Processing operations related to processing received transmissions in the uplink or over backhaul may include operations such as receive beamforming, demodulating received symbols, and decoding received symbols. In some embodiments, the processor 276 implements the transmit beamforming and/or receive beamforming based on beam direction information (e.g. BAI) received from the T-TRP 170. In some embodiments, the processor 276 may generate signaling, e.g. to configure one or more parameters of the ED 110. In some embodiments, the NT-TRP 172 implements physical layer processing, but does not implement higher layer functions such as functions at the medium access control (MAC) or radio link control (RLC) layer. As this is only an example, more generally, the NT-TRP 172 may implement higher layer functions in addition to physical layer processing.

The NT-TRP 172 further includes a memory 278 for storing information and data. Although not illustrated, the processor 276 may form part of the transmitter 272 and/or part of the receiver 274. Although not illustrated, the memory 278 may form part of the processor 276.

The processor 276, the processing components of the transmitter 272, and the processing components of the receiver 274 may each be implemented by the same or different one or more processors that are configured to execute instructions stored in a memory, e.g. in the memory 278. Alternatively, some or all of the processor 276, the processing components of the transmitter 272, and the processing components of the receiver 274 may be implemented using dedicated circuitry, such as a programmed FPGA, a hardware accelerator (e.g., a GPU or AI accelerator), or an ASIC. In some embodiments, the NT-TRP 172 may actually be a plurality of NT-TRPs that are operating together to serve the ED 110, e.g. through coordinated multipoint transmissions.

The T-TRP 170, the NT-TRP 172, and/or the ED 110 may include other components, but these have been omitted for the sake of clarity.

One or more steps of the embodiment methods provided herein may be performed by corresponding units or modules, according to FIG. 4. FIG. 4 illustrates units or modules in a device, such as in the ED 110, in the T-TRP 170, or in the NT-TRP 172. For example, a signal may be transmitted or output by a transmitting unit or by a transmitting module. A signal may be received or input by a receiving unit or by a receiving module. A signal may be processed by a processing unit or a processing module. Other steps may be performed by an artificial intelligence (AI) or machine learning (ML) module. The respective units or modules may be implemented using hardware, one or more components or devices that execute software, or a combination thereof. For instance, one or more of the units or modules may be a circuit such as an integrated circuit. Examples of an integrated circuit includes a programmed FPGA, a GPU, or an ASIC. For instance, one or more of the units or modules may be logical such as a logical function performed by a circuit, by a portion of an integrated circuit, or by software instructions executed by a processor. It will be appreciated that where the modules are implemented using software for execution by a processor for example, the modules may be retrieved by a processor, in whole or part as needed, individually or together for processing, in single or multiple instances, and that the modules themselves may include instructions for further deployment and instantiation.

While not shown, the transmitting module and the receiving module may be part of, or combined into, a transceiver module. A transceiver module may also be known as an interface module, or simply an interface, for inputting and outputting operations.

Additional details regarding the EDs 110, the T-TRP 170, and the NT-TRP 172 are known to those of skill in the art. As such, these details are omitted here.

The channel coding module in communications systems encode K source bits into N code bits to provide error correction capability against adversary channel conditions such as noise and interference. The code rate is R=K/N. In practice, the code rate R is selected according to channel quality.

Polar codes are capacity-achieving codes and thus a great breakthrough in coding theory. As code length approaches infinity, the synthesized channels (also known as subchannels, which are created by or associated with the polar code) become either noiseless or pure noise. The noiseless subchannels are utilized to transport information, and their proportion is proven to achieve the channel capacity defined by Shannon. The above-mentioned channel polarization phenomenon occurs under successive cancellation (SC) or SC-based decoding, which has a relatively low complexity.

Rate matching is performed after channel encoding, by either puncturing/shortening or repeating some code bits. The purpose of this operation is to obtain a code bit sequence of desired length for transmission over limited channel resources.

Channel interleaving is applied after channel encoding and rate matching by permuting the code bits. The purpose is to provide stable or superior performance under high-order modulation or in a fading channel.

Hybrid automatic repeat request (HARQ) is a mechanism to provide reliable wireless transmission. It combines forward error correction (FEC) and automatic repeat request (ARQ). In HARQ, the initial transmission is a FEC code word with means (such as CRC bits) to support error detection at the receiver. If a decoding error is detected, the receiver will send back a negative acknowledgment (NACK) signaling to inform the transmitter of the error, and request a retransmission. The retransmitted bits can be directly selected from the initially transmitted bits, or incrementally generated code bits which form a longer code word with the initially transmitted bits. The former approach is called chase-combining HARQ (CC-HARQ) and the latter approach is called incremental-redundancy HARQ (IR-HARQ). Typically, IR-HARQ outperforms CC-HARQ with the additional coding gain from incremental redundancy.

Polar codes belong to the class of linear block codes. For a polar code of length N, its generator matrix is G_{N}, and its encoding process is

$${x}_{1}^{N} = {u}_{1}^{N} {G}_{N} , where {u}_{1}^{N} = [ {u}_{1} , {u}_{2} , … , {u}_{N} ]$$

is the binary information vector,

$${x}_{1}^{N} = [ {x}_{1} , {x}_{2} , … , {x}_{N} ]$$

is the binary code vector. The N×N binary matrix

$${G}_{N} = {F}_{2}^{⊗ n} , where {F}_{2} = [ \begin{matrix}1 & 0 \\ 1 & 1\end{matrix} ]$$

is the polarization kernel matrix, n=log₂ N, and ⊗ is Kronecker product.

Typically, there are K information bits to be encoded into N code bits. Accordingly, the inequality K<N is given to obtain a code rate R=K/N<1. That implies only part of

$${u}_{1}^{N}$$

is used to carry information bits, and the rest are typically called frozen bits. Denote by I the information bit set (or information set), and F the frozen bit set (or frozen set), respectively. Sometimes, there is an additional PC bit set, denoted by P. The frozen bits are known (usually all zeros, but may also be other known values or sequences) before decoding, so they do not carry any payload information. The PC bits are parity-check bits generated from a subset of information bits. Therefore, the PC bits are known once the associated information bits are decoded. The decoding of polar codes attempts to recover all information bits.

The transmitted code length M may not always be the power of 2, i.e., M<N. In practice, puncturing and shortening are used to reduce transmitted code bits from N to M. For convenience, the present disclosure hereinafter refers to N as the mother code length, and M as the code length. In particular, punctured bits are non-transmitted bits unknown to the decoder, but shortened bits are non-transmitted bits known to the decoder (usually all zeros).

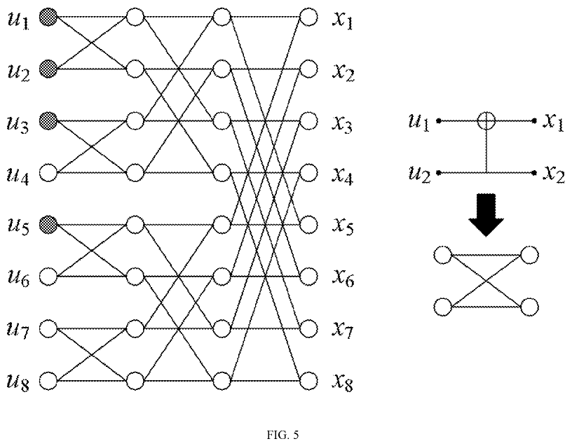

An example of a polar code with N=8, K=4 is shown in a trellis graph as shown in FIG. 5. Each “butterfly” in the graph represents a polarization, i.e.,

$${x}_{1}^{2} = {u}_{1}^{2} [ \begin{matrix}1 & 0 \\ 1 & 1\end{matrix} ] .$$

In this example, the information set is I={u₄, u₆, u₇, u₈}, and the frozen set is F={u₁, u₂, u₃, u₅}.

Successive cancellation (SC) is the basic decoding algorithm for polar codes, where all the frozen bits and information bits are decoded sequentially, i.e., bit by bit. The preceding bits are typically always decoded first.

Successive cancellation list (SCL) is an enhanced decoding algorithm for polar codes, where multiple (e.g., a number L) SC decoding instances are executed. Each instance is called a “decoding path”. When decoding each binary bit, both “0” and “1” branches are extended to each path, creating 2L paths. Then, all 2L paths are compared, where the most likely L paths are kept, and the least likely L paths are discarded (or pruned). These path extension and pruning operations are performed during decoding of every information bit, until all information bits are decoded. At last, the most likely path is selected as the decoding output.

CRC-aided successive cancellation list (CA-SCL) works almost the same as SCL, except that in the last step, the most likely path that passes CRC check is selected as the decoding output.

Parity-check successive cancellation list (PC-SCL) works almost the same as SCL, except that when decoding parity-check (PC) bits, the parity check value of associated preceding bits is used as the bit decision result. PC bits may be considered a type of bit in addition to frozen bits and information bits.

Rate-compatible polar coding is a desirable technology for wireless applications. In one example of polar code rate matching, a combination of puncturing, shortening and repetition is used together with a fixed reliability sequence to balance performance and complexity. In particular, subblock-wise interlacing and interleaving is used for both puncturing and shortening. The puncturing and shortening patterns are symmetric.

With mother code length N, and code length M, the specific rate matching scheme used is
Repetition, when M>N;
Puncturing, when K/M≤ 7/16;
Shortening, when K/M> 7/16;

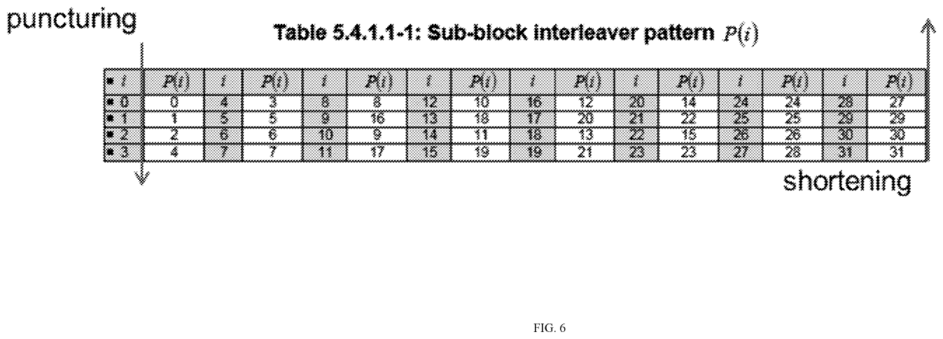

A subblock-wise interleaving is performed before puncturing and shortening. The interleaver partitions the length-N mother code into 32 subblocks of size N/32 and interlaces them. An example interleaver scheme is shown in FIG. 6. FIG. 6 shows a sub-block interleaver pattern table reproduced from a 3GPP standard specification.

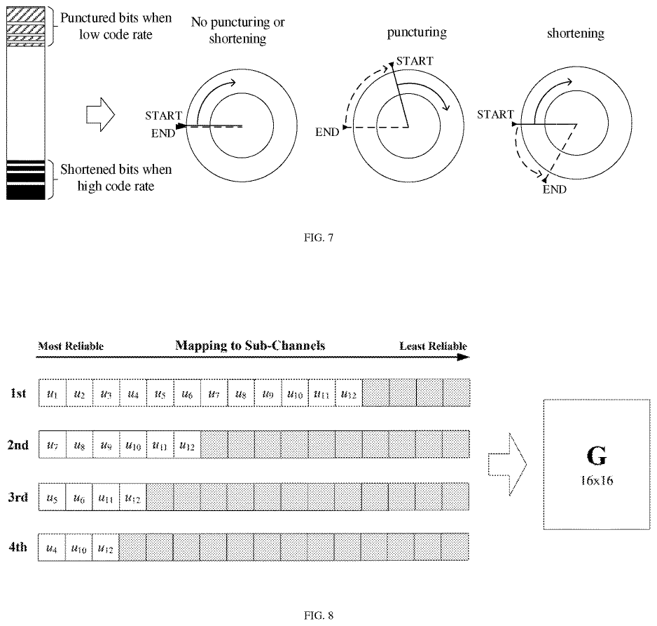

Since puncturing is performed from the 1^{st} code bit, and shortening is performed from the last code bit, the rate matching module is efficiently implemented through a cyclic buffer. All mother code bits are placed in the cyclic buffer, and puncturing is done by selecting the bits in clockwise order, and shortening is done by selecting bits in counter-clockwise order. The cyclic buffer is illustrated in FIG. 7.

Another polar code rate matching example involves an incremental freezing HARQ method, where transmissions of multiple short code words are supported. As more short codes are transmitted, the overall code length increases, and the overall code rate decreases.

In the first transmission, an (M₁, K) polar code is constructed, encoded and transmitted. The code rate is R₁=K/M₁. Usually, the code rate is determined such that R₁<C₁, where C₁ is the channel capacity of the first transmission. But in the case of faded channel or inaccurate channel estimation, there may be inequality R₁>C₁, and decoding will fail and a second transmission is required.

In the second transmission, K₂ least reliable information bits are selected from the K information bits in the first transmission. In practice, K₂ is chosen according to the estimated channel capacity of the second transmission. An (M₂, K₂) polar code is constructed accordingly and encoded and transmitted. However, if R₂>C₂, and decoding will fail again and a third transmission is required.

The third and fourth transmissions are constructed similarly, and so on.

At the receiver side, the decoder should always decode the last received code word, because it has the lowest code rate and thus the best chance of successful decoding. After the last transmission is correctly decoded, the corresponding information bits in all previous transmissions become known, and can be decoded as frozen bits with known values. This process is repeated as more code words are decoded, until all Kbits in the first transmission is decoded. The term “incremental freezing” refers to the operations to additionally freeze some information bits in the previous transmissions once a later transmitted code word is decoded.

An example is illustrated in FIG. 8, where M₁=M₂=M₃=M₄=16, and K₁=12, K₂=6, K₃=4, K₄=3.

Parity-check (PC) polar codes may be used to improve minimum distance of polar codes. PC polar codes may also be used to support IR-HARQ. In the latter case, the PC bits are used to couple multiple retransmissions into a longer polar code with extra coding gain.

The PC functions used for IR-HARQ may be considered a special case, where some information bits are copied from the initial transmitted code block to a retransmitted code block. This one-to-one parity checking between the two shorter code blocks effectively couples the two code blocks into a longer code block.

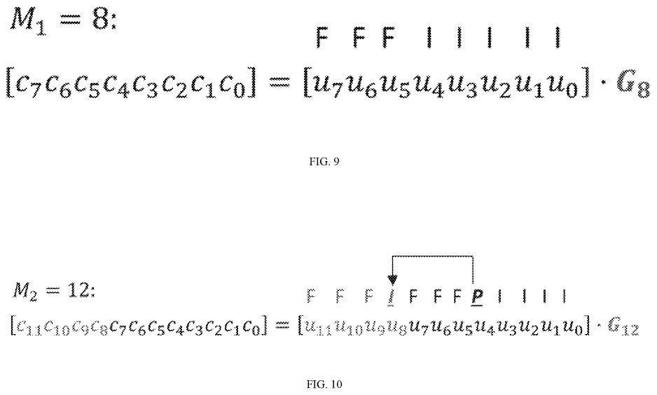

For example, the initial transmission is a (M₁=8, K=5) polar code, where {u₀, u₁, u₂, u₃, u₄} is the information set, and {u₅, u₆, u₇} is the frozen set. Its encoding process is illustrated in FIG. 9.

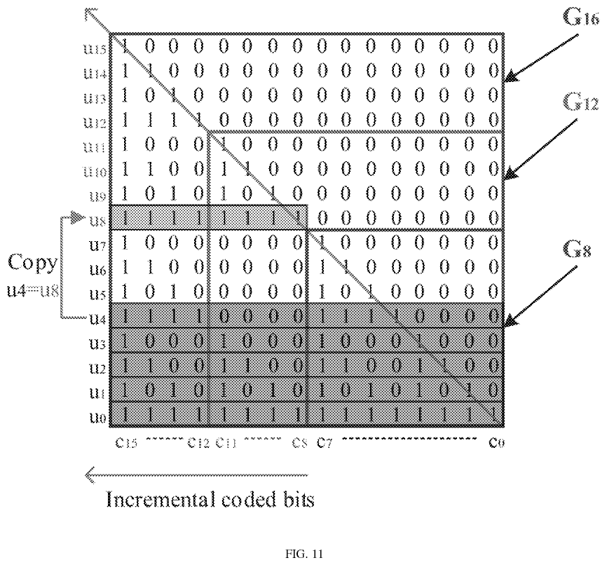

In the first retransmission, four additional code bits are transmitted. These four bits are coupled with the initially transmitted 8 bits to form a (M₂=12, K=5) polar code. The coupling is achieved by copying the value of u₄ to u₅ during encoding, thus generating a PC function u₄+u₈=0 (or equivalently u₈=u₄). As said, the largest index in this PC function corresponds to the PC bit (here u₈). During decoding, u₄ decoded as an information bit, while u₅ is decoded as a PC bit using u₈=u₄. With {u₀, u₁, u₂, u₃, u₅} as the information set, {u₄} as the PC set, and {u₅, u₆, u₇, u₉, u₁₀, u₁₁} as the frozen set, the encoding process is illustrated in FIG. 10.

In the second retransmission, the remaining four bits c₁₂, c₁₃, c₁₄, c₁₅ are transmitted to form a (M₃=16, K=5) polar code. But this time no new PC bits are generated.

From the polar transform matrix point of view, the three transmissions with effective code lengths M₁=8, M₂=12, M₃=16, are illustrated in FIG. 11.

As discussed above, rate matching may include a subblock-wise interleaver. In practice, implementations of rate matching schemes for Polar, LDPC, and Turbo codes involve code bit interleaving before bit selection. In these implementations, the code bit interleaving step is a serial process, which may result in a bottleneck for high-throughput applications. In particular, currently envisioned 6G specifications target peak throughput up to 1 Tbps; serial operations in some implementations of rate matching interleavers may become a bottleneck.

Some aspects of the present disclosure relate to one or more rateless polar IR-HARQ features.

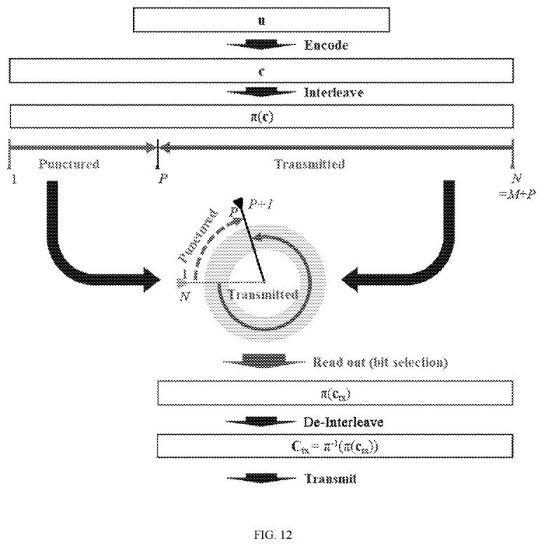

For an interleaver-based rate matching scheme, a de-interleaver may be added at the encoder side to cancel the “change-of-ordering” effect introduced during the previous interleaving step:
a. The steps from encoding until reading out from the rate matching circular buffer to obtain the rate matching output sequence include: encoding, rate matching interleaving, writing into circular buffer, and reading out from it.
b. A step called “de-interleaving” is applied to the rate matching output sequence, such that the relative ordering of code bits to be transmitted is the same as that of the non-interleaved code word.
   i. As illustrated in FIG. 12, denote by c the codeword before rate matching interleaving, and cₜₓ the code bits for transmission. The ordering of bits in c and cₜₓ should be exactly the same.

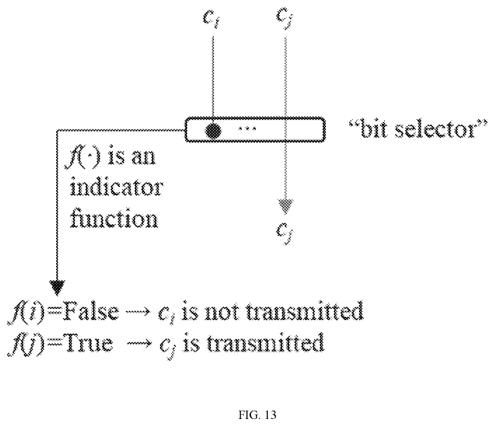

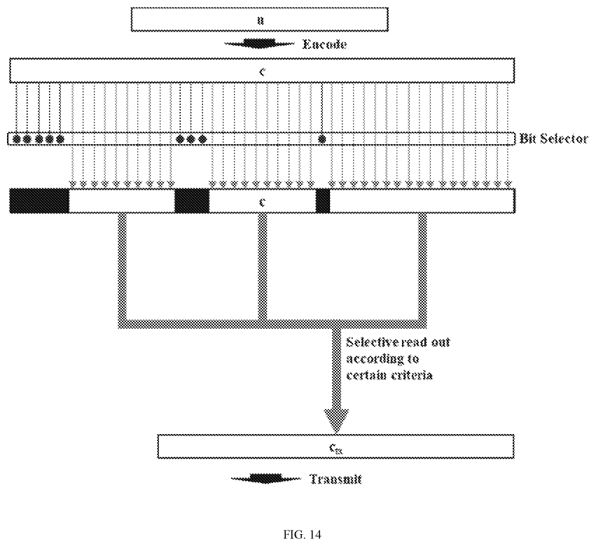

Another approach omits, removes, or bypasses the rate matching interleaver entirely, and introduces or replaces the interleaver with new ways to select a subset of code bits as the rate matching output sequence for transmission:
a. Instead of using a rate matching interleaver to select the transmitted code bits, directly apply a “bit selector”, which is an indicator function f(·) to determine whether a code bit with a particular index is to be transmitted or not. The indicator function, illustrated in FIG. 13, may include the following variables as inputs:
   i. The bit index in the codeword, denoted by i (or j);
   ii. The rate matching output length E;
   iii. The mother code length N;
b. All code bits obtained after encoding will pass through the indicators. The bits that can pass the indicator function (with certain output values from the function) will be selected for transmission, and the remaining bits that fail to pass the indicator function will be either punctured or shortened. This process can be made in parallel such that the overall throughput can be greatly increased. An illustration is given in FIG. 14.

The above mentioned two schemes, i.e., the interleaver-based rate matching and the interleaver-free rate matching can be combined, and a switch can be configured to choose between the two schemes based on the scenario and some pre-defined parameters, such as:
a. If the application scenario is ultra-high throughput (e.g., toward 1 Tbps or immersive communications), then the interleaver-free rate matching scheme is employed; otherwise if the application scenario does not require ultra-high throughput (such as mMTC, or hyper reliable and low-latency communications, or HRLLC), the interleaver-based rate matching scheme is used.
b. For LDPC codes, if certain base graph(s) are used, then the interleaver-free rate matching scheme is employed; otherwise the interleaver-based rate matching scheme is used. An example of a base graph is “base graph 1” defined in the 5G NR specification. Alternatively, another suitable base graph could be a newly defined or introduced base graph designed for high-throughput communications.
c. For LDPC codes or polar codes, if a certain MCS index is selected, where the MCS index is larger than a threshold, then the interleaver-free rate matching scheme is employed; otherwise the interleaver-based rate matching scheme is used.

Embodiments of the present disclosure include a description of steps in the coding chain, as well as the design for indicator functions.

Embodiments of the present disclosure include methods that may be applied to all suitable channel codes, including Polar codes, LDPC codes, and Turbo codes.

Embodiments of the present disclosure relating to “de-interleaving” and “interleaver-free” techniques can be applied to all interleavers in the encoding chain. For example, the channel interleaver placed at the end of the coding chain can also benefit from this scheme to achieve very high throughput.

FIG. 15 shows a schematic flowchart of a method for rate matching according to one or more example embodiments of the present disclosure. The method may be implemented by an apparatus, such as a rate matching apparatus, or other devices, such as a chip which has similar function. Optionally, the apparatus may be integrated into an encoder for encoding code bits to be transmitted by a transmitting device, such as a network device, a user equipment, an electronic device, which is not limited herein. As shown in FIG. 15, the method can include the following steps.
S1501, obtain a first bit sequence.
S1502, perform rate matching on the first bit sequence to obtain a second bit sequence, where code bits of the second bit sequence are included in the first bit sequence, and an ordering characteristic of the code bits in the second bit sequence conforms to an ordering characteristic of the code bits in the first bit sequence.

In the embodiment, the transmitting device obtains a first bit sequence, and performs rate matching on the first bit sequence to obtain a second bit sequence. Code bits of the second bit sequence are all selected from the first bit sequence, and thus are all included in the first bit sequence. After the rate matching, an ordering characteristic of the code bits in the second bit sequence conforms to an ordering characteristic of the code bits in the first bit sequence.

The first bit sequence may be obtained based on original data. In a possible implementation, the transmitting device may encode information bits by using a first encoding method to obtain the first bit sequence. A communication system may encode source bits into code bits to provide error correction capability against adversary channel conditions such as noise and interference. The first encoding method may include LDPC coding, Polar coding, Reed-Solomon (RS) coding, Turbo coding, or block coding (e.g., Bose-Chaudhuri-Hocquenghem (BCH) coding, Hamming coding), which is not limited here. By encoding the information bits using an appropriate method, the first bit sequence can be prepared to withstand the effects of channel impairments and noise, ensuring reliable and accurate transmission or storage of the data.

The ordering characteristic of code bits in a bit sequence refers to the relative arrangement or ordering of the code bits within the bit sequence. The ordering characteristic of the code bits in the second bit sequence conforms to the ordering characteristic of the code bits in the first bit sequence, which refers to that a relative ordering of code bits in the second bit sequence is the same as or is reverse to a relative ordering of code bits in the first bit sequence. In other words, if a specific code bit comes before another code bit in the first bit sequence, the same ordering is maintained in the second bit sequence in a case that the relative ordering of code bits in the second bit sequence is the same as the relative ordering of code bits in the first bit sequence, or the reverse ordering is maintained in the second bit sequence in a case that the relative ordering of code bits in the second bit sequence is reverse to the relative ordering of code bits in the first bit sequence.
S1503, output the second bit sequence.

In the embodiment, the transmitting device outputs the second bit sequence, the ordering characteristic of the code bits in which conforms to the ordering characteristic of the code bits in the first bit sequence.

In the present disclosure, the ordering characteristic of code bits of the rate matching output sequence (i.e. the second bit sequence) conforms to the ordering characteristic of code bits of the original sequence (i.e. the first bit sequence). There may be opportunities for hardware optimization or simplification.

In a possible implementation, the ordering characteristic may include a relative ordering of code bits, and the relative ordering of the code bits in the second bit sequence may be the same as the relative ordering of the code bits in the first bit sequence. When the relative ordering of the code bits in the second bit sequence is the same as the relative ordering of the code bits in the first bit sequence, the receiving side does not need to de-interleaving the second bit sequence during de-rate matching, that is, the receiving side does not need to rearrange the code bits of the second sequence to make the relative ordering of the code bits to be the same as that in the first bit sequence. Therefore, processing on the second bit sequence can be simplified on the receiving side and the overall efficiency and reliability of the communication system can be improved.

In a possible implementation, the relative ordering of code bits in the second bit sequence may be reverse to the relative ordering the code bits in the first code sequence. In this case, after obtaining the second bit sequence, the receiving side can just reverse the ordering of the code bits in the second sequence, or simply read the second bit sequence from the last code bit to the first code bits, to ensure the relative ordering of code bits is the same as the relative ordering of code bits in the first bit sequence. Therefore, the processing on the receiving side may still be simplified, and the throughput can be increased.

In a possible implementation, the transmitting device may perform rate matching on the first bit sequence by using a first mode or a second mode.

In the present disclosure, two different modes may be provided, and by using the first mode or the second mode to perform rate matching on the first bit sequence, code bits the obtained second bit sequence can have the same ordering characteristic as that of code bits of the first bit sequence. The first mode may be an interleaver-based rate matching scheme while the second mode may be an interleaver-free rate matching scheme.

In a possible implementation, the first mode may be used to rate matching the first bit sequence. The transmitting device may perform rate matching interleaving on the first bit sequence to obtain a third bit sequence, and may perform rate matching on the third bit sequence to obtain a fourth bit sequence. Then, the transmitting device may perform de-interleaving on the fourth bit sequence to obtain the second bit sequence.

Specifically, the transmitting device may obtain an interleaved bit sequence, i.e. the third bit sequence, by performing rate matching interleaving on the first bit sequence. The ordering of code bits in the third bit sequence is different from the ordering of code bits in the first bit sequence due to the rate matching interleaving. The rate matching interleaving is performed on the first bit sequence by rearranging the bits to facilitate bit selection.

Further, the transmitting device may perform rate matching on the third bit sequence by reading out a number of code bits from the third bit sequence, to obtain a fourth bit sequence. The rate matching is used to adapt the code rate of the transmitted code to the channel conditions and to match the available channel capacity. The number of code bits of the fourth bit sequence may be less than, equal to or larger than the number of code bits of the third bit sequence, and the specific number code bits of the fourth bit sequence may depend on a rate matching scheme actually used, which may be repetition, puncturing, or shortening. When the repetition is used, the number of code bits of the fourth bit sequence is larger than the number of code bits of the third bit sequence. When the puncturing or shortening is used, the number of code bits of the fourth bit sequence is less than the number of code bits of the third bit sequence. When there is no need to use the rate matching scheme, the number of code bits of the fourth bit sequence is equal to the number of code bits of the third bit sequence.

Since ordering of code bits in the fourth bit sequence is different from the ordering of code bits in the first bit sequence, de-interleaving may be performed on the fourth bit sequence to make code bits of the rate matching output sequence (i.e. the second bit sequence) conform to the ordering characteristic of the original encoded bit sequence (i.e. the first bit sequence).

By performing rate matching on the first bit sequence by using the first mode, the transmitting device can ensure that the code bits in the rate matching output sequence are arranged in an order conforming to their original order in the original bit sequence by performing de-interleaving on the fourth bit sequence. By exploiting this property, the decoder no longer needs a de-interleaver during de-rate matching, which can simplify the processing and hardware structure of the decoder and greatly increase the throughput.

In a possible implementation, the transmitting device may perform de-interleaving on the fourth bit sequence to obtain the second bit sequence by sorting the fourth bit sequence by a first order according to a rate matching scheme. By sorting the fourth bit sequence according to the defined order, the original order of code bits can be reconstructed to obtain the desired second bit sequence.

In a possible implementation, the rate matching scheme may include repetition or puncturing, and the first order may be ascending order. When the rate matching scheme is repetition or puncturing, the transmitting device may sort the fourth bit sequence by ascending order.

In a possible implementation, the rate matching scheme may include shortening, and the first order may be descending order. When the rate matching scheme is shortening, the transmitting device may sort the fourth bit sequence by descending order.

In a possible implementation, when rate matching the third bit sequence, the transmitting device may perform bit selection on the third bit sequence based on a rate matching scheme to obtain the fourth bit sequence. In a possible implementation, the transmitting device may perform bit selection on the third bit sequence by writing code bits of the third bit sequence into a buffer, and reading out code bits from the buffer starting from a first position according to the rate matching scheme to obtain the fourth bit sequence. The concept of the buffer can be implemented in both hardware and software, including using a vector or array data structure. The buffer, which can be a circular buffer, is a data structure that allows efficient storage and retrieval of elements in a circular manner. The interleaved code bits (i.e. the third bit sequence) are written into the buffer, and a segment of the bit sequence may be sequentially read out as the fourth bit sequence.

By employing bit selection from the buffer, the communication system can control the rate at which the interleaved code bits are extracted. This selective reading mechanism allows for precise adjustment of the data rate and facilitates the generation of the final output sequence based on the interleaved input bit sequence.

In a possible implementation, the rate matching scheme may include repetition or shortening, the first position may be a starting position of the third bit sequence. When the rate matching scheme is repetition or shortening, the transmitting device may read out code bits from the buffer starting from the starting position of the third bit sequence.

In a possible implementation, the rate matching scheme may include puncturing, and the first position may be a mother code length of the first bit sequence minus a rate matching output length. When the rate matching scheme is puncturing, the transmitting device may read out code bits from the buffer starting from the starting position as indicated by the mother code length of the first bit sequence minus the rate matching output length.

In a possible implementation, the transmitting device may write code bits of the third bit sequence into a buffer, and in a case that a starting position is pre-defined for a specific redundancy version, the transmitting device may read out code bits from the buffer starting from the starting position to obtain the fourth bit sequence, where the fourth bit sequence has a length determined according to a channel characteristic. If a starting position in the buffer is defined for a specific redundancy version, the transmitting device may read out code bits from the buffer starting from the defined starting position.

By performing bit selection from a starting position which is determined according to different rate matching schemes, the rate matching can be achieved, and the length and arrangement of the fourth bit sequence can be adjusted based on the channel or transmission requirements. In this way, the system can optimize the transmission performance and enhance error correction capabilities.

In a possible implementation, in a case that a starting position is pre-defined for a specific redundancy version, the transmitting device may sort the fourth bit sequence by ascending order. Specifically, when preparing an output sequence for a specific redundancy version, a starting position in the buffer may have been pre-defined for the specific redundancy version, the transmitting device may read out code bits from the pre-defined starting position to obtain the fourth bit sequence and then sort the fourth bit sequence by ascending order.

In a possible implementation, the transmitting device may perform rate matching interleaving on the first bit sequence by using an interleaver to obtain a third bit sequence, where the interleaver may include: a triangular interleaver, a block interleaver, a subblock interleaver, a bit-reversed interleaver, a cyclic shift interleaver, a pseudo-random interleaver, or a quadratic permutation polynomials (QPP) interleaver. The transmitting device may perform rate matching interleaving by using various interleavers according to actual needs. The use of various interleavers in rate matching interleaving enhances the system's ability to effectively handle diverse communication challenges, increase resilience to errors, and optimize the transmission of data.

Embodiments of the present disclosure relate to de-interleaving in the context of rate matching. A particular example of de-interleaving in the context of rate matching follows.

After the encoding, the coded bits are denoted by c₀, c₁, c₂, . . . , c_{N-1}, where N is the mother code length.

The rate matching interleaver π is denoted by π(0), π(1), . . . , π(N−1), which is a permutation of 0, 1, . . . , N−1.

The coded bits after interleaving is denoted by c_{π(0)}, c_{π(1)}, c_{π(2)}, . . . , c_{π(N-1)}.

The interleaved code bits are written into a circular buffer of length N, and a segment of the bit sequence is sequentially read out as the rate matching output sequence. This is called “bit selection”.

The starting position for reading out may depend on the rate matching scheme (repetition, puncturing, shortening) and redundancy version number (rν_{id}).

For example, if repetition or shortening is adopted, the bit selection can be described as:

for n = 0 to E − 1
c′ₙ = c_{π(n)};
end for

For example, if repetition or puncturing is adopted, the bit selection can be described as:

for n = 0 to E − 1
c′ₙ = c_{π(N-E+n)};
end for

For example, if a starting position s in the circular buffer is defined for a specific redundancy version, the bit selection can be described as:

for n = 0 to E − 1
c′ₙ = c_{π(s+n)};
end for

In the above, the rate matching output sequence is c′₀, c′₁, c′₂, . . . , c′_{E-1}.

Although these code bits constitute the final transmitted code bits, their ordering is different from the ordering in c₀, c₁, c₂, . . . , c_{N-1} due to the rate matching interleaver. Thus, an interleaver has to be implemented in hardware to satisfy the new ordering. As said, this interleaver is a bit-in-bit-out serial process that will slow down the whole encoding chain.

Therefore, if the rate matching output sequence c′₀, c′₁, c′₂, . . . , c′_{E-1} can maintain some ordering of the original encoded bit sequence c₀, c₁, c₂, . . . , c_{N-1}, an interleaver may be avoided with some hardware optimization.
Same ordering in c′₀, c′₁, c′₂, . . . , c′_{E-1} and c₀, c₁, c₂, . . . , c_{N-1};
Same ordering in c′₀, c′₁, c′₂, . . . , c′_{E-1} and c_{N-1}, c_{N-2}, . . . , c₁, c₀;
Reverse ordering in c′₀, c′₁, c′₂, . . . , c′_{E-1} and c₀, c₁, c₂, . . . , c_{N-1}; (equivalent to the previous one)

In general, define a de-interleaver π⁻¹ as denoted by π⁻¹(0), π⁻¹(1), . . . , π⁻¹(E−1), which is a permutation of 0, 1, . . . , E−1, such that c′_{π}_{^{−1}}₍₀₎, c′_{π}_{^{−1}}₍₁₎, c′_{π}_{^{−1}}₍₂₎, . . . , c′_{π}_{^{−1}}_{(E-1)} has the same code bits as c′₀, c′₁, c′₂, . . . , c′_{E-1}, but maintain the same or reverse ordering as in c₀, c₁, c₂, . . . , c_{N-1}.

For example, if repetition or puncturing is adopted, the bit selection can be described as:

Sort π(0), π(1), ... , π(E − 1) by ascending order to obtain π′(0), π′(1), ... ,
π′(E − 1);
for n = 0 to E − 1
c′ₙ = c_{π′(n)};
end for

For example, if shortening is adopted, the bit selection can be described as:

```
  Sort π(N − E), π(N − E + 1), ... , π(N − 1) by descending order to
obtain π′(0), π′(1), ... , π′(E − 1);
  for n = 0 to E − 1
    c′ₙ = c_{π′(n)};
  end for
```

For example, if a starting position s in the circular buffer is defined for a specific redundancy version, the bit selection can be described as:

```
  Sort π(s), π(s + 1), ... , π(s + E − 1) by ascending order to obtain
π′(0), π′(1), ... , π′(E − 1);
  for n = 0 to E − 1
    c′ₙ = c_{π′(n)};
  end for
```

The above-mentioned interleaver π can be any interleaver:
Triangular interleaver;
Block interleaver (e.g., row-in-column-out);
Subblock interleaver;
Bit-Reversed interleaver;
Cyclic shift interleaver;
Pseudo-random interleaver;
The quadratic permutation polynomials (QPP) interleaver;

A specific example of using a length-32 subblock interleaver is shown in the following example pseudocode.

The bits input to the rate matching interleaver are the coded bits d₀, d₁, d₂, . . . , d_{N-1}.

The rate matching interleaver J, is generated as follows:

```
for n = 0 to N − 1
  i = [32n/N];
  Jᵥ(n) = P(i) × (N/32) + mod( n, N/32);
end for
```

where the sub-block interleaver pattern P(i) can be either Table 1, or any length-32 sequence with elements [0,32).

TABLE 1
Sub-block interleaver pattern P(i)

| i | P(i) |
|---|---|
| 0 | 0 |
| 1 | 4 |
| 2 | 8 |
| 3 | 12 |
| 4 | 1 |
| 5 | 5 |
| 6 | 9 |
| 7 | 13 |
| 8 | 2 |
| 9 | 6 |
| 10 | 10 |
| 11 | 14 |
| 12 | 3 |
| 13 | 7 |
| 14 | 11 |
| 15 | 15 |
| 16 | 16 |
| 17 | 20 |
| 18 | 24 |
| 19 | 28 |
| 20 | 17 |
| 21 | 21 |
| 22 | 25 |
| 23 | 29 |
| 24 | 18 |
| 25 | 22 |
| 26 | 26 |
| 27 | 30 |
| 28 | 19 |
| 29 | 23 |
| 30 | 27 |
| 31 | 31 |

The rate matching output sequence is denoted by d′₀, d′₁, d′₂, . . . , d′_{E-1}.

J_{v,tx} [symbol] Jᵥ (0),Jᵥ(1),•••,Jᵥ(E − 1);
J′_{v,tx} [symbol] J′ᵥ(0),J′ᵥ(1),•••,J′ᵥ(E − 1) = sort(Jᵥ(0),Jᵥ(1),•••,Jᵥ(E − 1);
If puncturing is selected,
for n = 0 to E − 1
d′ₙ = d_{J′v(n)};
end for
Else if shortening is selected,
for n = 0 to E − 1
d′ₙ = d_{J′v(N-1-n)};
end for
Else if repetition is selected,
for n = 0 to E − 1
d′ₙ = d_{n%N};
end for
End if

The example above can ensure that the rate matching output sequence can be read out from the codeword according to its original order. By exploiting this property, the encoder can benefit from hardware optimizations that greatly increase the throughput; and the decoder no longer needs the de-interleaver and thus also greatly increases the throughput. However, the hardware description still has an interleaver and a sorter, which may be considered complex.

In some embodiments of the present disclosure, the interleaver and sorter can be entirely removed and replaced with a new interleaver-free design.

Such embodiments may be preferable due to a reduction in both standard description complexity and hardware implementation complexity.

In a possible implementation, the second mode, i.e. an interleaver-free rate matching scheme, may be used to rate matching the first bit sequence. The transmitting device may perform bit selection on the first bit sequence to obtain the second bit sequence by using a pre-defined function. In this way, the rate matching interleaver can be omitted, removed, or bypassed entirely, which simplifies the system structure and improves the communication efficiency. Further, the bit selection can be performed on the code bits in parallel such that the overall throughput can be greatly increased.

In a possible implementation, for each of code bits of the first bit sequence, the transmitting device may determine whether the respective code bit is to be transmitted by using the pre-defined function and according to a rate matching output length and a mother code length, and the transmitting device may obtain the second bit sequence according to code bits that are determined to be transmitted. The transmitting device may directly apply a preset indicator function to each code bit in the first bit sequence, to selectively choose which bits to transmit while adjusting the redundancy and throughput according to desired parameters, especially when the rate matching scheme is puncturing or shortening. By eliminating the need for a separate rate matching interleaver, the system complexity and processing time can be reduced. The use of a pre-defined function also enables the system to adapt to different transmission requirements and channel conditions, maximizing the use of available resources.

In a possible implementation, for each of code bits of the first bit sequence, the transmitting device may obtain a binary value by applying the pre-defined function on each of code bits of the first bit sequence, where the binary value is an output of the pre-defined function and may indicate whether to select the respective code bit into the second bit sequence. The transmitting device may determine whether the respective code bit is to be included in the second bit sequence according to a corresponding binary value to obtain the second bit sequence. In a possible implementation, an empty second bit sequence may be initialized. For each of code bits of the first bit sequence, the transmitting device may apply the pre-defined function on each of code bits of the first bit sequence to obtain a binary value. The binary value may represent true or false to indicate whether a code bit is to be transmitted. The transmitting device may determine whether a code bit is to be include in the second bit sequence according to the corresponding binary value for each of code bits of the first bit sequence, to obtain the second bit sequence to be output.

For example, the bit selection can be described as:

```
Second sequence = empty;
For {bit index i} in {all bit indices}
  If {pre-defined function returns true}
    Include {bit index i} in the second sequence
  Else
    Not include
  End if
End for
```

Output the second sequence

For example, the bit selection can be described as:

```
Second sequence = empty;
For {bit index i} in {all bit indices}
  If {pre-defined function returns true}
    Include {bit index i} in the second sequence
  Else
    Not include
  End if
    If {length of second sequence reaches pre-defined length}
      Break
    End if
End for
```

Output the second sequence
where the pre-defined length can be the rate matching output sequence length.

In a possible implementation, for each of code bits of the first bit sequence, the transmitting device may determine how many times each of the respective code bit is to be transmitted by using the pre-defined function and according to a rate matching output length and a mother code length, and may obtain the second bit sequence according to the times that each of the respective code bits are determined to be transmitted. The transmitting device may determine how many times each of the respective code bit is to be transmitted, especially when the rate matching scheme is repetition, and may obtain the second bit sequence according to the times that each of the respective code bits are determined to be transmitted. In this way, the rate matching can be achieved by eliminating the need for a separate rate matching interleaver, and the system complexity and processing time can be reduced.

Instead of using a rate matching interleaver to select the transmitted code bits, directly apply a “bit selector”, which is an indicator function f(·) to determine whether a code bit with a particular index is to be transmitted or not.

The indicator function may include the following variables as inputs:
The bit index in the codeword, denoted by i (or j);
The rate matching output length E;
The mother code length N;
Parameters related to a conceptual interleaver or circular buffer.

The indicator function may return the following outputs:
True representing the bit is selected for transmission; and false representing the bit is not selected for transmission;
A number, which is to be compared with a pre-defined value. If the output number is larger than (or smaller than) the pre-defined value, the bit is selected for transmission; otherwise if the output number is smaller than (or larger than) the pre-defined value, the bit is not selected for transmission.

In fact, the indicator function can be designed such that its effect is the equivalent to the previously mentioned “interleaver+de-interleaver” methods. For example, an indicator function can return “whether the bit index falls in the range of bit indices in the original codeword that will be selected for transmission”. In many cases, the indicator function is characterized by a very simple form that involves a few arithmetic operations and comparisons that can be efficiently implemented in hardware.

In a possible implementation, the pre-defined function may include: a function for a block interleaver, a function for a subblock interleaver, a function for a bit-reversed interleaver, a function for a cyclic shift interleaver. The function for an interleaver refers to a function which can perform similar functions as the corresponding interleaver.

In a possible implementation, the pre-defined function may include a function for a block interleaver, and the transmitting device may include at least one of the following steps:
comparing first position information of each code bit and a first threshold, where the first position information of each code bit is obtained according to an index of each code bit and dimension information of the block interleaver, and the first threshold is obtained according to the rate matching output length and the dimension information of the block interleaver;
determining, according to a comparing result, whether each code bit in the first bit sequence is to be transmitted.

The dimension information of the block interleaver may include the number of rows (m) and columns (n). The first position information of each code bit may be obtained according to an index of each code bit and dimension information of the block interleaver. For example, the first position information may be a row or a column where a code bit is located. The first threshold may be obtained according to the rate matching output length and the dimension information of the block interleaver. For example, the first threshold may be the rate matching output length divided by the number of rows. By using the function for a block interleaver, bit selection can be performed easily, which can simplify the rate matching, reduce computational complexity, and increase the overall throughput.

In a possible implementation, the pre-defined function may include a function for a subblock interleaver, and the transmitting device may include at least one of the following steps:
determining a rate matching scheme according to a code rate;
in a case that the rate matching scheme is puncturing, determining that each code bit belonging to a subblock with an index smaller than a fourth threshold is not to be transmitted and determining that each code bit belonging to a subblock with an index greater than the fourth threshold is to be transmitted; for code bits belonging to a subblock with an index equal to the fourth threshold, determining a code bit is not to be transmitted when an index of the code bit modulo a subblock length is smaller than a fifth threshold, and determining a code bit is to be transmitted when an index of the code bit modulo the subblock length is equal to or greater than the fifth threshold; where the fourth threshold and the fifth threshold are determined based on a rate matching output length, a mother code length and the subblock length; or
in a case that the rate matching scheme is shortening, determining that each code bit belonging to a subblock with an index smaller than a sixth threshold is to be transmitted and determining that each code bit belonging to a subblock with an index greater than the sixth threshold is not to be transmitted; for code bits belonging to a subblock with an index equal to the sixth threshold, determining a code bit is not to be transmitted when an index of the code bit modulo a subblock length is smaller than a seventh threshold, and determining a code bit is to be transmitted, when an index of the code bit modulo the subblock length is equal to or greater than the seventh threshold; where the sixth threshold and the seventh threshold are determined based on a rate matching output length and the subblock length.

The subblock interleaving divides the input sequence into smaller subblocks and then interleaves them without changing the bit ordering within each subblock. By using the function for a subblock interleaver to perform bit selection, high parallelism can be provided, thereby increasing the throughput of the system.

In an implementation, the pre-defined function may include a function for a bit-reversed interleaver, the transmitting device may include at least one of the following steps:
applying a bit-reversal function on an index of each code bit to obtain a bit-reversed index of each code bit;
determining a rate matching scheme according to a code rate;
in a case that the rate matching scheme is puncturing, determining whether each code bit is to be transmitted by comparing the bit-reversed index of each code bit and a second threshold, where the second threshold is determined by a rate matching output length and a mother code length; or
in a case that the rate matching scheme is shortening, determining whether each code bit is to be transmitted by comparing the bit-reversed index of each code bit and a third threshold, where the third threshold is determined by a rate matching output length.

In a possible implementation, in a case that a bit-reversed index of a code bit in the first bit sequence is less than the second threshold, the transmitting device may determine the code bit not to be transmitted; in a case that a bit-reversed index of a code bit in the first bit sequence is equal to or larger than the second threshold, the transmitting device may determine the code bit to be transmitted; where the second threshold is equal to the mother code length minus the rate matching output length.

In a possible implementation, in a case that a bit-reversed index of a code bit in the first bit sequence is less than the third threshold, the transmitting device may determine that the code bit is to be transmitted; in a case that a bit-reversed index of a code bit in the first bit sequence is equal to or larger than the third threshold, the transmitting device may determine that the code bit is not to be transmitted; where the third threshold is equal to the rate matching output length.

By using the function for a bit-reversed interleaver to perform bit selection, simplicity in implementation and low computational complexity can be achieved, and the requirements for memory resources are small.

In a possible implementation, the pre-defined function may include a function for a cyclic shift interleaver, and the transmitting device may perform at least one of the following steps:
obtaining third position information of each code bit in the first bit sequence by shifting an index of each code bit in the first bit sequence circularly by a pre-defined offset;
determining a rate matching scheme according to a code rate;
in a case that the rate matching scheme is puncturing, determining whether each code bit is to be transmitted by comparing the third position information of each code bit and a second threshold, where the second threshold is determined by a rate matching output length and a mother code length; or
in a case that the rate matching scheme is shortening, determining whether each code bit is to be transmitted by comparing the third position information of each code bit of each code bit and a third threshold, where the third threshold is determined by a rate matching output length.

In a possible implementation, in a case that third position information of a code bit in the first bit sequence is less than the second threshold, the transmitting device may determine that the code bit is not to be transmitted; in a case that third position information of a code bit in the first bit sequence is equal to or larger than the second threshold, the transmitting device may determine that the code bit is to be transmitted; where the second threshold is equal to the mother code length minus the rate matching output length.

In a possible implementation, in a case that third position information of a code bit in the first bit sequence is less than the third threshold, the transmitting device may determine that the code bit is to be transmitted; in a case that third position information of a code bit in the first bit sequence is equal to or larger than the third threshold, the transmitting device may determine that the code bit is not to be transmitted; where the third threshold is equal to the rate matching output length.

By using the function for a cyclic shift interleaver to perform bit selection, the position of code bits is adjusted and certain bits are selectively omitted based on the determined scheme, the system can optimize the use of available bandwidth and improve the robustness of data transmission against errors.

The following examples show an equivalent “bit selector” or indicator function for some widely used interleavers. Note that in the below examples, the bit index starts from 0. It may take values from [0, 1, . . . , N−1]. Thus, references to the i-th bit, will actually mean the (i+1)-th bit if the 1^{st}, bit is to have index 1 instead of index 0. The following examples can be straightforwardly modified to apply for cases with bit index starting from 1.

Block interleaver (e.g., row-in-column-out); if the block interleaver has m rows and n columns, and the rate matching output sequence has length E, the indicator function for the i-th code bit can be:

```
if (i%n < E/m)
  return true;
else if (i%n > E/m)
  return false;
else
  if ([i/n] < E%m)
    return true;
  else
    return false;
  end if
end if
```

Subblock interleaver; first divide the input sequence into subblocks, and then interleave the blocks without changing the bit ordering within a block. The code bits to be transmitted are read from the interleaved bit sequence in sequential order or reverse sequential order.

Suppose a length-M sub-block interleaver pattern P(i) is used and each subblock has B bits, e.g., that of NR Polar where M=32 and B=32, and the mother code length (or the length of the code bits) is N, then directly determine whether the i-th code bit should be transmitted or not.

The following case is for puncturing, i.e., when code rate is smaller than a threshold and thus puncturing is used

```
F=N−E;
T = [F /B];
if (i/B ∈ {P(0), P(1),..., P(T−1)})
  return false;
else if (i/B ∈ {P(T+1), P(T+2),..., P(M)})
  return true;
else
  if (i%B < F%B)
    return false;
  else
    return true;
  end if
end if
```

The following case is for shortening, i.e., when code rate is larger than a threshold and thus shortening is used

```
T = [E/B];
if (i/B ∈ {P(0), P(1),..., P(T−1)})
  return true;
else if (i/B ∈ {P(T+1), P(T+2),..., P(M)})
  return false;
else
  if (i%B < E%B)
    return true;
  else
    return false;
  end if
end if
```

Bit-Reversed interleaver; the bit indices of all the code bits are bit-reversed by a bit-reversal function. The code bits are then interleaved by ascending bit-reversed index order. The code bits to be transmitted are read from the interleaved bit sequence in sequential order (e.g., for puncturing) or reverse sequential order (e.g., for shortening).

The bit-reversal function, denoted by BitRev(x), is obtained by reversing the binary representation

$${b}_{x}^{{log}_{2} N} … {b}_{x}^{0}$$

of the integer x into

$${b}_{x}^{0} … {b}_{x}^{{log}_{2} N} ,$$

then represent it in decimal representation.

The following case is for puncturing, i.e., when code rate is smaller than a threshold and thus puncturing is used

```
F=N−E;
if (BitRev(i) < F)
  return false;
else
  return true;
end if
```

The following case is for shortening, i.e., when code rate is larger than a threshold and thus shortening is used

```
if (BitRev(i) < E)
  return true;
else
  return false;
end if
```

Cyclic shift interleaver; the code bits are circularly shifted by a pre-defined offset value Δ. For example, the new index for the j-th bit after interleaving will be (j+Δ)% N, where N is the mother code length or the length of the code bits.

The following case is for puncturing, i.e., when code rate is smaller than a threshold and thus puncturing is used

```
F=N−E;
if ((i-Δ)%N < F)
  return false;
else
  return true;
end if
```

The following case is for shortening, i.e., when code rate is larger than a threshold and thus shortening is used

```
if ((i − Δ)%N < E)
  return true;
else
  return false;
end if
```

An example of block puncturing and Bit-Reversed shortening in described below in a pseudocode example.

The bit sequence after the sub-block interleaver d′₀, d′₁, d′₂, . . . , d′_{N-1}, d_{N}, d_{N+1}, d_{N+2}, . . . , d_{2N-1} is written into a circular buffer of length M. If repetition or puncturing is selected as the rate matching scheme for the first transmission, M=2N; otherwise if shortening is selected, M=2E₀, where E₀ is the rate matching output sequence length for the first transmission. The circular buffer stores a bit sequence y₀, y₁, y₂, . . . y_{M-1}.

If repetition or puncturing is selected, the bit sequence y₀, y₁, y₂, . . . , y_{M-1} is generated as follows.

```
for n = 0 to N − 1
  yₙ = d_{2N-1-n};
end for
for n = N to 2N − 1
  yₙ = d′_{2N-1-n};
end for
```

Else if shortening is selected, the bit sequence y₀, y₁, y₂, . . . , y_{M-1} is generated as follows.

```
k =o
for n = 0 to N − 1
  if BitRev(N − 1 − n) < E₀
    yₖ = d_{2N-1-n};
  k = k + 1;
  end if
end for
for n = N to 2N − 1
  if BitRev(Jᵥ(2N − 1 − n)) < E₀
  yₖ = d′_{2N-1-n};
  k = k + 1;
  end if
end for
```

where BitRev(x) is obtained by reversing the binary representation

$${b}_{x}^{{log}_{2} N} … {b}_{x}^{0}$$

of the integer x into

$${b}_{x}^{0} … {b}_{x}^{{log}_{2} N} ,$$

then represent it in decimal representation.

In a possible implementation, the above mentioned two schemes, i.e., the interleaver-based rate matching and the interleaver-free rate matching can be combined, and a switch can be configured to choose between the two schemes based on the scenario and some pre-defined parameters.

In a possible implementation, the transmitting device may determine to perform rate matching on the first bit sequence by using a first mode or a second mode according to transmission requirement. The transmission requirement refers to the specific needs or criteria that dictate how data should be transmitted in the communication system. These requirements can vary depending on factors such as the application scenario, desired throughput, latency, reliability, and error correction capabilities. For example, the transmission requirement may include at least one of: throughput, latency, reliability, error correction capability, or modulation and coding scheme (MCS).

In a possible implementation, in a case that the transmission requirement is ultra-high throughput, the transmitting device may determine to perform rate matching on the first bit sequence by using the second mode; and in a case that the transmission requirement is a requirement other than ultra-high throughput, the transmitting device may determine to perform rate matching on the first bit sequence by using the first mode.

If the application scenario is ultra-high throughput (e.g., toward 1 Tbps or immersive communications), then the interleaver-free rate matching scheme may be employed; otherwise if the application scenario does not require ultra-high throughput (such as mMTC, or hyper reliable and low-latency communications, or HRLLC), the interleaver-based rate matching scheme may be used.

In a possible implementation, the first encoding method includes LDPC coding, and in a case that a preset base graph is used, the transmitting device may determine to perform rate matching on the first bit sequence by using a second mode; in a case that a base graph other than the preset base graph is used, the transmitting device may determine to perform rate matching on the first bit sequence by using a first mode. In a possible implementation, the preset base graph comprises a base graph designed for a high-throughput communication.

For LDPC codes, if certain base graph(s) are used, then the interleaver-free rate matching scheme is employed; otherwise the interleaver-based rate matching scheme is used. An example of a base graph is “base graph 1” defined in the 5G NR specification. Alternatively, another suitable base graph could be a newly defined or introduced base graph designed for high-throughput communications.

In a possible implementation, the first encoding method may include LDPC coding or polar coding, in a case that a preset MCS index is used, the transmitting device may determine to perform rate matching on the first bit sequence by using a second mode; and in a case that an MCS index other than the preset MCS index is used, the transmitting device may determine to perform rate matching on the first bit sequence by using a first mode.

For LDPC codes or polar codes, if a certain MCS index is selected, where the MCS index is larger than a threshold, then the interleaver-free rate matching scheme is employed; otherwise the interleaver-based rate matching scheme is used.

The ability to determine which mode to use based on transmission requirements gives the system flexibility to adapt to different scenarios. By selecting the appropriate mode for rate matching, the system can allocate resources effectively, the communication efficiency can be improved, and optimized performance metrics in the communication system can be achieved.

Some embodiments of the present disclosure relate to switching between two modes or schemes of rate matching.

The above mentioned two schemes, i.e., the interleaver-based rate matching and the interleaver-free rate matching can be combined, and a switch can be configured to choose between the two schemes based on the scenario and some pre-defined parameters, such as:
a. If the application scenario is ultra-high throughput (e.g., toward 1 Tbps or immersive communications), then the interleaver-free rate matching scheme is employed; otherwise if the application scenario does not require ultra-high throughput (such as mMTC, or hyper reliable and low-latency communications, or HRLLC), the interleaver-based rate matching scheme is used.
b. For LDPC codes, if certain base graph(s) are used, then the interleaver-free rate matching scheme is employed; otherwise the interleaver-based rate matching scheme is used. The said base graph can be a base graph 1 in 5G NR, or a newly introduced base graph designed for high-throughput communications.

Example pseudocodes of switching methods may have the following structure:

```
if certain BG is selected
  read out from the input sequence;
    if (the indicator function returns true)
      add the current bit to the output sequence;
    end if
else
  interleave the input sequence;
  read out from the input sequence;
    if (the output sequence length is smaller than E)
      add the current bit to the output sequence;
    end if
end if
transmit the output sequence;
```

c. For LDPC codes or polar codes, if certain MCS index is selected, where the MCS index is larger than a threshold, then the interleaver-free rate matching scheme is employed; otherwise the interleaver-based rate matching scheme is used.

Example pseudocodes of switching methods may have the following structure:

```
if MCS_index > T
  read out from the input sequence;
    if (the indicator function returns true)
      add the current bit to the output sequence;
    end if
else
  interleave the input sequence;
  read out from the input sequence;
    if (the output sequence length is smaller than E)
      add the current bit to the output sequence;
    end if
end if
transmit the output sequence;
```

According to embodiments of the present disclosure, a transmitting device obtains a first bit sequence, performs rate matching on the first bit sequence to obtain a second bit sequence, where code bits of the second bit sequence are included in the first bit sequence, and an ordering characteristic of the code bits in the second bit sequence conforms to an ordering characteristic of the code bits in the first bit sequence, and the transmitting device outputs the second bit sequence. In this way, the rate matching process can preserve a desired ordering characteristic of a bit sequence, there may be opportunities for hardware optimization or simplification. Correspondingly, the receiving device may not need to de-interleave the received bit sequence during de-rate matching. That is to say, the receiving device is not necessary to equip with a de-interleaver for de-rate matching.

Some embodiments of the present disclosure may enable advantageous effects such as:
Low complexity and higher parallelism.
Simple description for standard-friendly specification.
Higher throughput and lower latency.

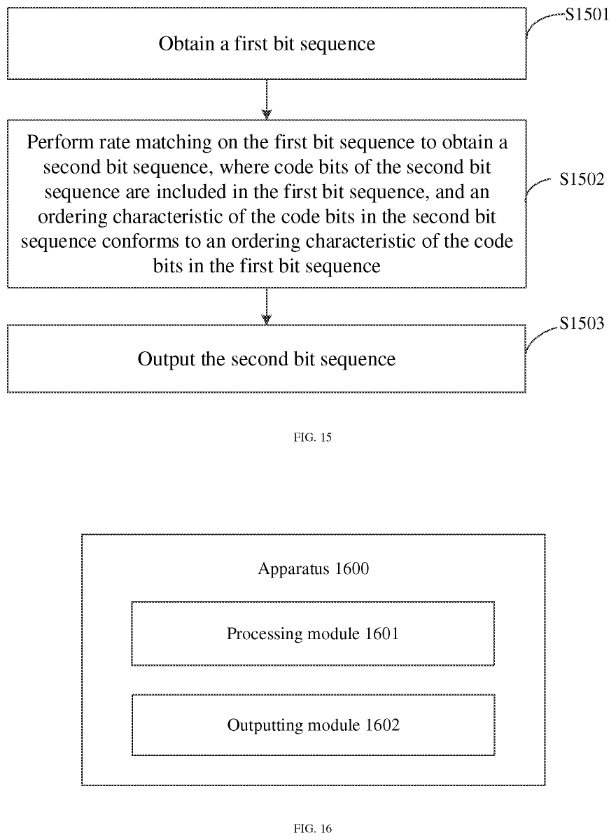

FIG. 16 shows a schematic structural diagram of an apparatus according to one or more example embodiments of the present disclosure. The apparatus may be a rate matching apparatus or other devices, such as a chip which has similar function, or installed in or applied to a chip, such as an encoder, in the transmitting device or any other equipment, module, circuit or unit that can implement the steps in above method embodiments. As shown in FIG. 16, the apparatus 1600 may include:
a processing module 1601, configured to:
obtain a first bit sequence;
perform rate matching on the first bit sequence to obtain a second bit sequence, where code bits of the second bit sequence are included in the first bit sequence, and an ordering characteristic of the code bits in the second bit sequence conforms to an ordering characteristic of the code bits in the first bit sequence;
an outputting module 1602, configured to output the second bit sequence.

In a possible implementation, the processing module 1601 is configured to:
encode information bits by using a first encoding method to obtain the first bit sequence.

In a possible implementation, the ordering characteristic includes a relative ordering of code bits, and the ordering characteristic of the code bits in the second bit sequence conforming to an ordering characteristic of the code bits in the first bit sequence includes:
the relative ordering of the code bits in the second bit sequence is the same as the relative ordering of the code bits in the first bit sequence.

In a possible implementation, the processing module 1601 is configured to: perform rate matching on the first bit sequence by using a first mode or a second mode.

In a possible implementation, the processing module 1601 is configured to: perform rate matching interleaving on the first bit sequence to obtain a third bit sequence;
perform rate matching on the third bit sequence by reading out a number of code bits from the third bit sequence, to obtain a fourth bit sequence, where the number of code bits of the fourth bit sequence is less than, equal to or larger than the number of code bits of the third bit sequence; and
perform de-interleaving on the fourth bit sequence to obtain the second bit sequence.

In a possible implementation, the processing module 1601 is configured to:
sort the fourth bit sequence by a first order according to a rate matching scheme.

In a possible implementation, the rate matching scheme includes repetition or puncturing, and the first order is ascending order.

In a possible implementation, the rate matching scheme includes shortening, and the first order is descending order.

In a possible implementation, the processing module 1601 is configured to:
perform bit selection on the third bit sequence based on a rate matching scheme to obtain the fourth bit sequence.

In a possible implementation, the processing module 1601 is configured to:
write code bits of the third bit sequence into a buffer; and
read out code bits from the buffer starting from a first position according to the rate matching scheme to obtain the fourth bit sequence.

In a possible implementation, the rate matching scheme includes repetition or shortening, the first position is a starting position of the third bit sequence.

In a possible implementation, the rate matching scheme includes puncturing, and the first position is a mother code length of the first bit sequence minus a rate matching output length.

In a possible implementation, the processing module 1601 is configured to:
write code bits of the third bit sequence into a buffer; and
in a case that a starting position is pre-defined for a specific redundancy version, read out code bits from the buffer starting from the starting position to obtain the fourth bit sequence, where the fourth bit sequence has a length determined according to a channel characteristic.

In an implementation, the processing module 1601 is configured to:
in a case that a starting position is pre-defined for a specific redundancy version, sort the fourth bit sequence by ascending order.

In an implementation, the processing module 1601 is configured to:
perform rate matching interleaving on the first bit sequence to obtain a third bit sequence by using an interleaver;
where the interleaver includes: a triangular interleaver, a block interleaver, a subblock interleaver, a bit-reversed interleaver, a cyclic shift interleaver, a pseudo-random interleaver, or a quadratic permutation polynomials (QPP) interleaver.

In an implementation, the processing module 1601 is configured to:
perform bit selection on the first bit sequence to obtain the second bit sequence by using a pre-defined function.

In an implementation, the processing module 1601 is configured to:
determine, for each of code bits of the first bit sequence, whether the respective code bit is to be transmitted by using the pre-defined function and according to a rate matching output length and a mother code length; and
obtain the second bit sequence according to code bits that are determined to be transmitted.

In an implementation, the processing module 1601 is configured to:
obtain, for each of code bits of the first bit sequence, a binary value by applying the pre-defined function on each of code bits of the first bit sequence, where the binary value, which is an output of the pre-defined function corresponding to each of the code bits, indicates whether to select the respective code bit into the second bit sequence;
obtain the second bit sequence based on the binary value of each of the code bits of the first bit sequence.

In a possible implementation, the processing module 1601 is configured to:
determine, for each of code bits of the first bit sequence, how many times each of the respective code bit is to be transmitted by using the pre-defined function and according to a rate matching output length and a mother code length; and
obtain the second bit sequence according to the times that each of the respective code bits are determined to be transmitted.

In a possible implementation, the pre-defined function includes: a function for a block interleaver, a function for a subblock interleaver, a function for a bit-reversed interleaver, a function for a cyclic shift interleaver.

In a possible implementation, the pre-defined function includes a function for a block interleaver, and the processing module 1601 is configured to perform the at least one of the following steps:
comparing first position information of each code bit and a first threshold, where the first position information of each code bit is obtained according to an index of each code bit and dimension information of the block interleaver, and the first threshold is obtained according to the rate matching output length and the dimension information of the block interleaver;
determining, according to a comparing result, whether each code bit in the first bit sequence is to be transmitted.

In a possible implementation, the pre-defined function includes a function for a subblock interleaver, and the processing module 1601 is configured to perform at least one of the following steps:
determining a rate matching scheme according to a code rate;
in a case that the rate matching scheme is puncturing, determining that each code bit belonging to a subblock with an index smaller than a fourth threshold is not to be transmitted and determining that each code bit belonging to a subblock with an index greater than the fourth threshold is to be transmitted; for code bits belonging to a subblock with an index equal to the fourth threshold, determining a code bit is not to be transmitted when an index of the code bit modulo a subblock length is smaller than a fifth threshold, and determining a code bit is to be transmitted when an index of the code bit modulo the subblock length is equal to or greater than the fifth threshold; where the fourth threshold and the fifth threshold are determined based on a rate matching output length, a mother code length and the subblock length; or
in a case that the rate matching scheme is shortening, determining that each code bit belonging to a subblock with an index smaller than a sixth threshold is to be transmitted and determining that each code bit belonging to a subblock with an index greater than the sixth threshold is not to be transmitted; for code bits belonging to a subblock with an index equal to the sixth threshold, determining a code bit is not to be transmitted when an index of the code bit modulo a subblock length is smaller than a seventh threshold, and determining a code bit is to be transmitted, when an index of the code bit modulo the subblock length is equal to or greater than the seventh threshold; where the sixth threshold and the seventh threshold are determined based on a rate matching output length and the subblock length.

In a possible implementation, the pre-defined function includes a function for a bit-reversed interleaver, and the processing module 1601 is configured to perform at least one of the following steps:
applying a bit-reversal function on an index of each code bit to obtain a bit-reversed index of each code bit;
determining a rate matching scheme according to a code rate;
in a case that the rate matching scheme is puncturing, determining whether each code bit is to be transmitted by comparing the bit-reversed index of each code bit and a second threshold, where the second threshold is determined by a rate matching output length and a mother code length; or
in a case that the rate matching scheme is shortening, determining whether each code bit is to be transmitted by comparing the bit-reversed index of each code bit and a third threshold, where the third threshold is determined by a rate matching output length.

In a possible implementation, the processing module 1601 is configured to:
in a case that a bit-reversed index of a code bit in the first bit sequence is less than the second threshold, determine the code bit not to be transmitted;
in a case that a bit-reversed index of a code bit in the first bit sequence is equal to or larger than the second threshold, determine the code bit to be transmitted;
where the second threshold is equal to the mother code length minus the rate matching output length.

In a possible implementation, the processing module 1601 is configured to:
in a case that a bit-reversed index of a code bit in the first bit sequence is less than the third threshold, determining that the code bit is to be transmitted;
in a case that a bit-reversed index of a code bit in the first bit sequence is equal to or larger than the third threshold, determining that the code bit is not to be transmitted;
where the third threshold is equal to the rate matching output length.

In a possible implementation, the pre-defined function includes a function for a cyclic shift interleaver, and the processing module 1601 is configured to perform at least one of the following steps:
obtaining third position information of each code bit in the first bit sequence by shifting an index of each code bit in the first bit sequence circularly by a pre-defined offset;
determining a rate matching scheme according to a code rate;
in a case that the rate matching scheme is puncturing, determining whether each code bit is to be transmitted by comparing the third position information of each code bit and a second threshold, where the second threshold is determined by a rate matching output length and a mother code length; or
in a case that the rate matching scheme is shortening, determining whether each code bit is to be transmitted by comparing the third position information of each code bit of each code bit and a third threshold, where the third threshold is determined by a rate matching output length.

In a possible implementation, the processing module 1601 is configured to:
in a case that third position information of a code bit in the first bit sequence is less than the second threshold, determine that the code bit is not to be transmitted;
in a case that third position information of a code bit in the first bit sequence is equal to or larger than the second threshold, determine that the code bit is to be transmitted;
where the second threshold is equal to the mother code length minus the rate matching output length.

In a possible implementation, the processing module 1601 is configured to:
in a case that third position information of a code bit in the first bit sequence is less than the third threshold, determine that the code bit is to be transmitted;
in a case that third position information of a code bit in the first bit sequence is equal to or larger than the third threshold, determine that the code bit is not to be transmitted;
where the third threshold is equal to the rate matching output length.

In a possible implementation, the processing module 1601 is configured to:
determine to perform rate matching on the first bit sequence by using a first mode or a second mode according to transmission requirement.

In a possible implementation, the processing module 1601 is configured to:
in a case that the transmission requirement is ultra-high throughput, determine to perform rate matching on the first bit sequence by using a second mode;
in a case that the transmission requirement is a requirement other than ultra-high throughput, determine to perform rate matching on the first bit sequence by using a first mode.

In a possible implementation, the first encoding method includes a LDPC code, the processing module 1601 is configured to:
in a case that a preset base graph is used, determine to perform rate matching on the first bit sequence by using a second mode;
in a case that a base graph other than the preset base graph is used, determine to perform rate matching on the first bit sequence by using a first mode.

In a possible implementation, the preset base graph includes a base graph designed for a high-throughput communication.

In a possible implementation, the first encoding method includes a LDPC code or a polar code, the processing module 1601 is configured to:
in a case that a preset MCS index is used, determine to perform rate matching on the first bit sequence by using a second mode;
in a case that an MCS index other than the preset MCS index is used, determine to perform rate matching on the first bit sequence by using a first mode.

It should be understood by a person skilled in the art that, the relevant description of the above modules in the possible implementations of the present disclosure may be understood with reference to the relevant description of the interleaving method in the possible implementations of the present disclosure. The technical effect achieved by the above apparatus is similar as that achieved by the above possible method implementations, which is not repeated herein.

An embodiment of the present disclosure provides an apparatus including processing circuitry for executing any of the above methods. It should be understood that the apparatus can execute the steps in the above method embodiments, which will not be repeated here.

An embodiment of the present disclosure provides an encoder including the apparatus described above with reference to FIG. 16 or the apparatus including processing circuitry for executing any of the above methods as described above.

An embodiment of the present disclosure provides an electronic device including an encoder for executing any of the above methods.

An embodiment of the present disclosure provides a wireless communication apparatus which includes a processor and a memory. The memory is storing instructions that cause the processor to perform any of the above methods.

An embodiment of the present disclosure provides a wireless communication system, including a transmitting device and a receiving device. The transmitting device is configured to execute the steps in any of the above methods.

An embodiment of the present disclosure provides a computer-readable medium storing computer execution instructions which, when executed by a processor, causes the processor to execute any of the above methods.

An embodiment of the present disclosure provides a computer program product including computer execution instructions which, when executed by a processor, causes the processor to execute any of the above methods.

The present disclosure encompasses various embodiments, including not only method embodiments, but also other embodiments such as apparatus embodiments and embodiments related to non-transitory computer readable storage media. Embodiments may incorporate, individually or in combinations, the features disclosed herein.

Although this disclosure refers to illustrative embodiments, this is not intended to be construed in a limiting sense. Various modifications and combinations of the illustrative embodiments, as well as other embodiments of the disclosure, will be apparent to persons skilled in the art upon reference to the description.

Features disclosed herein in the context of any particular embodiments may also or instead be implemented in other embodiments. Method embodiments, for example, may also or instead be implemented in apparatus, system, and/or computer program product embodiments. In addition, although embodiments are described primarily in the context of methods and apparatus, other implementations are also contemplated, as instructions stored on one or more non-transitory computer-readable media, for example. Such media could store programming or instructions to perform any of various methods consistent with the present disclosure.

Although the present disclosure describes methods and processes with steps in a certain order, one or more steps of the methods and processes may be omitted or altered as appropriate. One or more steps may take place in an order other than that in which they are described, as appropriate.

Note that the expression “at least one of A or B”, as used herein, is interchangeable with the expression “A and/or B”. It refers to a list in which you may select A or B or both A and B. Similarly, “at least one of A, B, or C”, as used herein, is interchangeable with “A and/or B and/or C” or “A, B, and/or C”. It refers to a list in which you may select: A or B or C, or both A and B, or both A and C, or both B and C, or all of A, B and C. The same principle applies for longer lists having a same format.

Although the present disclosure is described, at least in part, in terms of methods, a person of ordinary skill in the art will understand that the present disclosure is also directed to the various components for performing at least some of the aspects and features of the described methods, be it by way of hardware components, software or any combination of the two. Accordingly, the technical solution of the present disclosure may be embodied in the form of a software product. A suitable software product may be stored in a pre-recorded storage device or other similar non-volatile or non-transitory computer readable medium, including DVDs, CD-ROMs, USB flash disk, a removable hard disk, or other storage media, for example. The software product includes instructions tangibly stored thereon that enable a processing device (e.g., a personal computer, a server, or a network device) to execute examples of the methods disclosed herein. The machine-executable instructions may be in the form of code sequences, configuration information, or other data, which, when executed, cause a machine (e.g., a processor or other processing device) to perform steps in a method according to examples of the present disclosure.

The present disclosure may be embodied in other specific forms without departing from the subject matter of the claims. The described example embodiments are to be considered in all respects as being only illustrative and not restrictive. Selected features from one or more of the above-described embodiments may be combined to create alternative embodiments not explicitly described, features suitable for such combinations being understood within the scope of this disclosure.

All values and sub-ranges within disclosed ranges are also disclosed. Also, although the systems, devices and processes disclosed and shown herein may include a specific number of elements/components, the systems, devices and assemblies could be modified to include additional or fewer of such elements/components. For example, although any of the elements/components disclosed may be referenced as being singular, the embodiments disclosed herein could be modified to include a plurality of such elements/components. The subject matter described herein intends to cover and embrace all suitable changes in technology.

Although embodiments have been described above with reference to the accompanying drawings, those of skill in the art will appreciate that variations and modifications may be made without departing from the scope thereof as defined by the appended claims.

### ACRONYMS, ABBREVIATIONS, AND INITIALISMS

| Full Name | Acronym/Abbreviation/Initialism |
|---|---|
| Long Term | LTE |
| Evolution | |
| New Radio | NR |
| Forward error | FEC |
| correction | |
| Multiple Access | MA |
| Quality of Service | QoS |
| low-density parity | LDPC |
| check codes | |
| cyclic redundancy | CRC |
| check | |
| Parity check | PC |
| ultra-reliable low | uRLLC |
| latency | |
| communications | |
| Enhanced mobile | eMBB |
| broadband | |
| massive Machine | mMTC |
| Type | |
| Communications | |
| non-terrestrial | NTN |
| networks | |
| Internet of Things | IoT |
| Bit Error Rate | BER |
| Block Error Rate | BLER |
| Packet Error Rate | PER |
| Spectral Efficiency | SE |
| Hybrid automatic | HARQ |
| repeat request | |
| Incremental- | IR-HARQ |
| redundancy HARQ | |
| Channel Quality | CQI |
| Indicator | |
| Modulation Coding | MCS |
| Scheme | |
| gNodeB or 5G base | gNB |
| station | |
| user equipment | UE |
| Radio Resource | RRC |
| Control | |
| Radio Network | RNTI |
| Temporary | |
| Identifier | |
| Uplink Control | UCI |
| Information | |
| Downlink Control | DCI |
| Information | |
| Physical Broadcast | PBCH |
| Channel | |
| Half-radio frame bit | HRF |
| Synchronization | SSB |
| Signal Block | |
| unequal error | UEP |
| protection | |
| variable node | VN |
| check node | CN |
| Log-likelihood ratio | LLR |
| Successive | SC |
| cancellation | |
| Successive | SCL |
| cancellation list | |
| CRC-aided | CA-SCL |
| successive | |
| cancellation list | |
| Parity-check | PC-SCL |
| successive | |
| cancellation list | |

What is claimed is:

1. A method comprising:
obtaining a first bit sequence;
performing rate matching on the first bit sequence to obtain a second bit sequence, wherein code bits of the second bit sequence are comprised in the first bit sequence, and an ordering characteristic of the code bits in the second bit sequence conforms to an ordering characteristic of the code bits in the first bit sequence; and
outputting the second bit sequence.

2. The method of claim 1, wherein the obtaining the first bit sequence comprises:
encoding information bits by using a first encoding method to obtain the first bit sequence, wherein the ordering characteristic comprises a relative ordering of code bits, and wherein the ordering characteristic of the code bits in the second bit sequence conforming to an ordering characteristic of the code bits in the first bit sequence comprises the relative ordering of the code bits in the second bit sequence is the same as the relative ordering of the code bits in the first bit sequence.

3. The method of claim 2, wherein the performing the rate matching on the first bit sequence to obtain the second bit sequence comprises:
performing the rate matching on the first bit sequence by using a first mode or a second mode.

4. The method of claim 3, wherein the performing the rate matching on the first bit sequence by using the first mode comprises:
performing rate matching interleaving on the first bit sequence to obtain a third bit sequence;
performing rate matching on the third bit sequence by reading out a number of code bits from the third bit sequence, to obtain a fourth bit sequence, wherein the number of code bits of the fourth bit sequence is less than, equal to, or larger than the number of code bits from the third bit sequence; and
performing de-interleaving on the fourth bit sequence to obtain the second bit sequence.

5. The method of claim 3, wherein the performing the rate matching on the first bit sequence by using the second mode comprises:
performing, by using a pre-defined function, bit selection on the first bit sequence to obtain the second bit sequence.

6. The method of claim 3, wherein the performing the rate matching on the first bit sequence by using the first mode or the second mode comprises:
determining, according to a transmission requirement, to perform the rate matching on the first bit sequence by using the first mode or the second mode.

7. The method of claim 3, wherein the first encoding method comprises low-density parity-check (LDPC) coding, and wherein the performing the rate matching on the first bit sequence by using the first mode or the second mode comprises:
based on that a preset base graph is used, determining to perform the rate matching on the first bit sequence by using the second mode; or
based on that a base graph other than the preset base graph is used, determining to perform the rate matching on the first bit sequence by using the first mode.

8. The method of claim 3, wherein the first encoding method comprises LDPC coding or polar coding, and wherein the performing the rate matching on the first bit sequence by using the first mode or the second mode comprises:
based on that a preset modulation coding scheme (MCS) index is used, determining to perform the rate matching on the first bit sequence by using the second mode; or
based on that an MCS index other than the preset MCS index is used, determining to perform the rate matching on the first bit sequence by using the first mode.

9. An apparatus comprising:
at least one processor; and
memory coupled to the at least one processor and storing instructions that, when executed by the at least one processor, cause the apparatus to perform operations including:
obtaining a first bit sequence;
performing rate matching on the first bit sequence to obtain a second bit sequence, wherein code bits of the second bit sequence are comprised in the first bit sequence, and an ordering characteristic of the code bits in the second bit sequence conforms to an ordering characteristic of the code bits in the first bit sequence; and
outputting the second bit sequence.

10. The apparatus of claim 9, wherein the obtaining the first bit sequence comprises:
encoding information bits by using a first encoding method to obtain the first bit sequence, wherein the ordering characteristic comprises a relative ordering of code bits, and wherein the ordering characteristic of the code bits in the second bit sequence conforming to an ordering characteristic of the code bits in the first bit sequence comprises the relative ordering of the code bits in the second bit sequence is the same as the relative ordering of the code bits in the first bit sequence.

11. The apparatus of claim 10, wherein the performing the rate matching on the first bit sequence to obtain the second bit sequence comprises:
performing the rate matching on the first bit sequence by using a first mode or a second mode.

12. The apparatus of claim 11, wherein the performing the rate matching on the first bit sequence by using the first mode comprises:
performing rate matching interleaving on the first bit sequence to obtain a third bit sequence;
performing rate matching on the third bit sequence by reading out a number of code bits from the third bit sequence, to obtain a fourth bit sequence, wherein the number of code bits of the fourth bit sequence is less than, equal to or larger than the number of code bits from the third bit sequence; and
performing de-interleaving on the fourth bit sequence to obtain the second bit sequence.

13. The apparatus of claim 11, wherein the performing the rate matching on the first bit sequence by using the second mode comprises:
performing, by using a pre-defined function, bit selection on the first bit sequence to obtain the second bit sequence.

14. The apparatus of claim 11, wherein the performing the rate matching on the first bit sequence by using the first mode or the second mode comprises:
determining, according to a transmission requirement, to perform the rate matching on the first bit sequence by using the first mode or the second mode.

15. The apparatus of claim 11, wherein the first encoding method comprises low-density parity-check (LDPC) coding, and wherein the performing the rate matching on the first bit sequence by using the first mode or the second mode comprises:
based on that a preset base graph is used, determining to perform the rate matching on the first bit sequence by using the second mode; or
based on that a base graph other than the preset base graph is used, determining to perform the rate matching on the first bit sequence by using the first mode.

16. The apparatus of claim 11, wherein the first encoding method comprises LDPC coding or polar coding, and wherein the performing the rate matching on the first bit sequence by using the first mode or the second mode comprises:
based on that a preset modulation coding scheme (MCS) index is used, determining to perform the rate matching on the first bit sequence by using the second mode; or
based on that an MCS index other than the preset MCS index is used, determining to perform the rate matching on the first bit sequence by using the first mode.

17. A non-transitory computer-readable storage medium storing instructions that, when executed by an apparatus, cause the apparatus to perform operations including:
obtaining a first bit sequence;
performing rate matching on the first bit sequence to obtain a second bit sequence, wherein code bits of the second bit sequence are comprised in the first bit sequence, and an ordering characteristic of the code bits in the second bit sequence conforms to an ordering characteristic of the code bits in the first bit sequence; and
outputting the second bit sequence.

18. The non-transitory computer-readable storage medium of claim 17, wherein the obtaining the first bit sequence comprises:
encoding information bits by using a first encoding method to obtain the first bit sequence, wherein the ordering characteristic comprises a relative ordering of code bits, and wherein the ordering characteristic of the code bits in the second bit sequence conforming to an ordering characteristic of the code bits in the first bit sequence comprises the relative ordering of the code bits in the second bit sequence is the same as the relative ordering of the code bits in the first bit sequence.

19. The non-transitory computer-readable storage medium of claim 17, wherein the performing the rate matching on the first bit sequence to obtain the second bit sequence comprises:
performing the rate matching on the first bit sequence by using a first mode or a second mode.

20. The non-transitory computer-readable storage medium of claim 19, wherein the performing the rate matching on the first bit sequence by using the first mode comprises:
performing rate matching interleaving on the first bit sequence to obtain a third bit sequence;
performing rate matching on the third bit sequence by reading out a number of code bits from the third bit sequence, to obtain a fourth bit sequence, wherein the number of code bits of the fourth bit sequence is less than, equal to or larger than the number of code bits from the third bit sequence; and
performing de-interleaving on the fourth bit sequence to obtain the second bit sequence.
